(19) United States
(12) Patent Application Publication
(10) Pub. No.: US 2025/0203873 A1
(43) Pub. Date: Jun. 19, 2025

(54) SEMICONDUCTOR DEVICE INCLUDING VERTICAL CHANNEL

(71) Applicant: Samsung Electronics Co., Ltd., Suwon-si (KR)

(72) Inventors: Dongsung CHOI, Suwon-si (KR); Byongju KIM, Suwon-si (KR); Youjung KIM, Suwon-si (KR); Jeongmin LEE, Suwon-si (KR); Changheon CHEON, Suwon-si (KR)

(73) Assignee: Samsung Electronics Co., Ltd., Suwon-si (KR)

(21) Appl. No.: 18/982,103

(22) Filed: Dec. 16, 2024

(30) Foreign Application Priority Data
Dec. 19, 2023 (KR) 10-2023-0186152

(51) Int. Cl. H10B 51/20; H01L 23/00; H01L 25/00; H01L 25/065; H01L 25/18; H10B 51/10; H10B 51/40; H10B 80/00

(52) U.S. Cl. CPC H10B 51/20; H01L 24/08; H01L 24/80; H01L 25/0657; H01L 25/18; H01L 25/50; H10B 51/10; H10B 51/40; H10B 80/00; H01L 2224/08145; H01L 2224/80895; H01L 2224/80896; H01L 2924/1431; H01L 2924/1441

(57) ABSTRACT

A semiconductor device is provided, including a peripheral circuit structure, and a cell structure on the peripheral circuit structure and including a cell region and a connection region. The cell structure includes gate electrodes and mold insulating layers alternately in a first direction in the cell region and the connection region, a channel structure penetrating through the gate electrodes and extending in the first direction, a cell plug contacting a first gate electrode among the gate electrodes in the connection region and penetrating through second gate electrodes below the first gate electrode among the gate electrodes, and insulating spacers on a sidewall of the cell plug and spaced apart from each other in the first direction, each of the insulating spacers between each of the second gate electrodes and the sidewall of the cell plug.

### CROSS-REFERENCE TO RELATED APPLICATION

This application is based on and claims priority under 35 U.S.C. § 119 to Korean Patent Application No. 10-2023-0186152, filed on Dec. 19, 2023, in the Korean Intellectual Property Office, the disclosure of which is incorporated by reference herein in its entirety.

### BACKGROUND

The inventive concepts relate to semiconductor devices, and more particularly, to semiconductor devices including a vertical channel.

Electronic systems requiring data storage need a semiconductor device capable of storing high-capacity data. Accordingly, research is being carried out on a solution for increasing the data storage capacity of a semiconductor device. For example, a semiconductor device including three-dimensionally arranged memory cells instead of two-dimensionally arranged memory cells has been proposed as a method of increasing the data storage capacity of a semiconductor device.

### SUMMARY

The inventive concepts provide semiconductor devices having improved integration and good electrical characteristics.

According to some aspects of the inventive concepts, there is provided a semiconductor device including a peripheral circuit structure, and a cell structure on the peripheral circuit structure and including a cell region and a connection region. The cell structure includes gate electrodes and mold insulating layers alternately in a first direction perpendicular to an upper surface of the peripheral circuit structure in the cell region and the connection region, a channel structure penetrating through the gate electrodes and extending in the first direction, a cell plug contacting a first gate electrode among the gate electrodes in the connection region and penetrating through second gate electrodes below the first gate electrode among the gate electrodes, and insulating spacers on a sidewall of the cell plug and spaced apart from each other in the first direction, each of the insulating spacers between each of the second gate electrodes and the sidewall of the cell plug.

According to some aspects of the inventive concepts, there is provided a semiconductor device including a peripheral circuit structure and a cell structure on the peripheral circuit structure and including a cell region and a connection region. The cell structure includes gate electrodes and mold insulating layers alternately in a first direction perpendicular to an upper surface of the peripheral circuit structure in the cell region and the connection region, a channel structure penetrating through the gate electrodes and extending in the first direction, a cell plug contacting a first gate electrode among the gate electrodes in the connection region and penetrating through second gate electrodes below the first gate electrode among the gate electrodes, and insulating spacers on a first side surface portion of a sidewall of the cell plug, each of the insulating spacers between each of the second gate electrodes and the first side surface portion of the sidewall of the cell plug. A second side surface portion of the sidewall of the cell plug is in contact with the mold insulating layers.

According to some aspects of the inventive concepts, there is provided a semiconductor device including a peripheral circuit structure and a cell structure on the peripheral circuit structure and including a cell region and a connection region. The cell structure includes gate electrodes and mold insulating layers alternately in a first direction perpendicular to an upper surface of the peripheral circuit structure in the cell region and the connection region, a channel structure penetrating through the gate electrodes and extending in the first direction in the cell region, a stack cover insulating layer below a lowest gate electrode among the gate electrodes in the cell region and the connection region, a cell plug contacting a first gate electrode among the gate electrodes in the connection region, penetrating through second gate electrodes below the first gate electrode among the gate electrodes, and including a first end close to the peripheral circuit structure and a second end opposite to the first end, insulating spacers on a first side surface portion of a sidewall of the cell plug, each of the insulating spacers between each of the second gate electrodes and the first side surface portion of the sidewall of the cell plug, and a bit line below the channel structure and electrically connected to the channel structure. A second side surface portion of the sidewall of the cell plug is in contact with the mold insulating layers.

### BRIEF DESCRIPTION OF THE DRAWINGS

Example embodiments will be more clearly understood from the following detailed description taken in conjunction with the accompanying drawings in which:

FIG. 1 is a block diagram of a semiconductor device according to some example embodiments;

FIG. 2 is an equivalent circuit diagram of a memory cell array of a semiconductor device according to some example embodiments;

FIG. 3 is a perspective view of a representative structure of a semiconductor device according to some example embodiments;

FIG. 4 is a plan view of the semiconductor device of FIG. 3;

FIG. 5 is a cross-sectional view of the semiconductor device taken along line A-A′ in FIG. 4;

FIG. 6 is an enlarged view of a portion CX of FIG. 5;

FIG. 7 is a cross-sectional view of a semiconductor device according to some example embodiments;

FIG. 8 is an enlarged view of a portion CX of FIG. 7.

FIG. 9 is a cross-sectional view of a semiconductor device according to some example embodiments;

FIG. 10 is an enlarged view of a portion CX of FIG. 9;

FIG. 11 is a cross-sectional view of a semiconductor device according to some example embodiments;

FIG. 12 is a cross-sectional view of a semiconductor device according to some example embodiments;

FIG. 13 is a cross-sectional view of a semiconductor device according to some example embodiments;

FIGS. 14 through 30 are cross-sectional views illustrating a method of manufacturing a semiconductor device 100, according to some example embodiments, wherein FIGS. 14 through 17A, 18A, 19A, 20 through 22, 23A, 24A, and 25 through 30 are cross-sectional views corresponding to cross-sections taken along line A-A′ of FIG. 4, and FIGS. 17B, 18B, 19B, 23B, and 24B are enlarged views of CX portions of FIGS. 17A, 18A, 19A, 23A, and 24A.

### DETAILED DESCRIPTION OF THE EMBODIMENTS

Example embodiments will now be described fully with reference to the accompanying drawings.

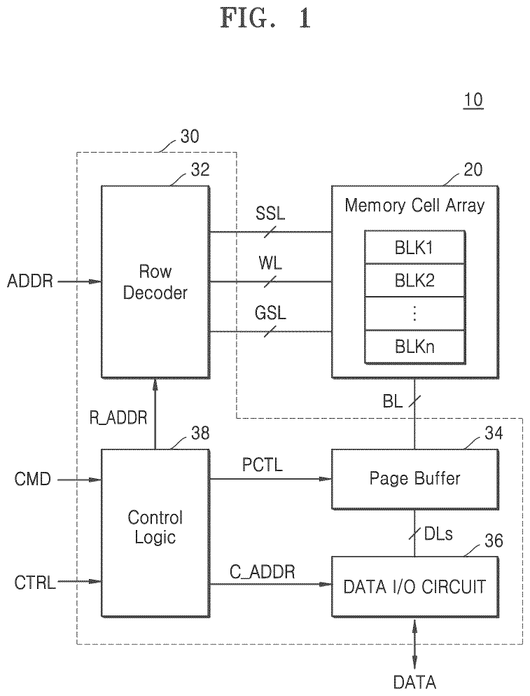

FIG. 1 is a block diagram of a semiconductor device 10 according to some example embodiments.

Referring to FIG. 1, the semiconductor device 10 may include a memory cell array 20 and a peripheral circuit 30. The memory cell array 20 includes a plurality of memory cell blocks BLK1, BLK2, through to BLKn. Each of the plurality of memory cell blocks BLK1, BLK2, through to BLKn may include a plurality of memory cells. The plurality of memory cell blocks BLK1, BLK2, through to BLKn may be connected to the peripheral circuit 30 via a bit line BL, a word line WL, a string select line SSL, and a ground select line GSL.

The peripheral circuit 30 may include a row decoder 32, a page buffer 34, a data input/output (I/O) circuit 36, and a control logic 38. Although not shown in FIG. 1, the peripheral circuit 30 may further include an (I/O) interface, a column logic, a voltage generator, a pre-decoder, a temperature sensor, a command decoder, an address decoder, an amplification circuit, and the like.

The memory cell array 20 may be connected to the page buffer 34 via the bit line BL and may be connected to the row decoder 32 via the word line WL, the string selection line SSL, and the ground selection line GSL. In the memory cell array 20, the plurality of memory cells included in the plurality of memory cell blocks BLK1, BLK2, through to BLKn may be flash memory cells. The memory cell array 20 may include a three-dimensional memory cell array. The three-dimensional memory cell array may include a plurality of NAND strings, each of which may include a plurality of memory cells respectively connected to a plurality of word lines WL vertically stacked on a substrate.

The peripheral circuit 30 may receive an address ADDR, a command CMD, and/or a control signal CTRL from the outside of the semiconductor device 10 and may transmit and/or receive data DATA to or from a device outside the semiconductor device 10.

In response to the address ADDR, the row decoder 32 may select at least one memory cell block from the plurality of memory cell blocks BLK1, BLK2, through to BLKn and select a word line WL, a string select line SSL, and a ground select line GSL of the selected memory cell block. The row decoder 32 may transmit a voltage for performing a memory operation to the word line of the selected memory cell block.

The page buffer 34 may be connected to the memory cell array 20 via the bit lines BL. The page buffer 34 may operates as a write driver during a program operation to apply a voltage according to the data DATA desired to be stored in the memory cell array 20 to the bit line BL and may operate as a sense amplifier during a read operation to sense the data DATA stored in the memory cell array 20. The page buffer 34 may operate according to a control signal PCTL received from the control logic 38.

The data I/O circuit 36 may be connected to the page buffer 34 via data lines DLs. The data I/O circuit 36 may receive the data DATA from a memory controller (not shown) during a program operation and may provide program data DATA to the page buffer 34 based on a column address C_ADDR received from the control logic 38. During a read operation, the data I/O circuit 36 may provide, to the memory controller, read data DATA stored in the page buffer 34 based on the column address C_ADDR received from the control logic 38.

The data I/O circuit 36 may transmit an input address or instruction to the control logic 38 or the row decoder 32. The peripheral circuit 30 may further include an electro static discharge (ESD) circuit and a pull-up/pull-down driver.

The control logic 38 may receive the command CMD and the control signal CTRL from the memory controller. The control logic 38 may provide a row address R_ADDR to the row decoder 32 and may provide the column address C_ADDR to the data I/O circuit 36. The control logic 38 may generate various internal control signals that are used within the semiconductor device 10, in response to the control signal CTRL. For example, the control logic 38 may adjust the level of a voltage that is provided to the word lines WL and the bit lines BL during a memory operation, such as a program operation or an erase operation.

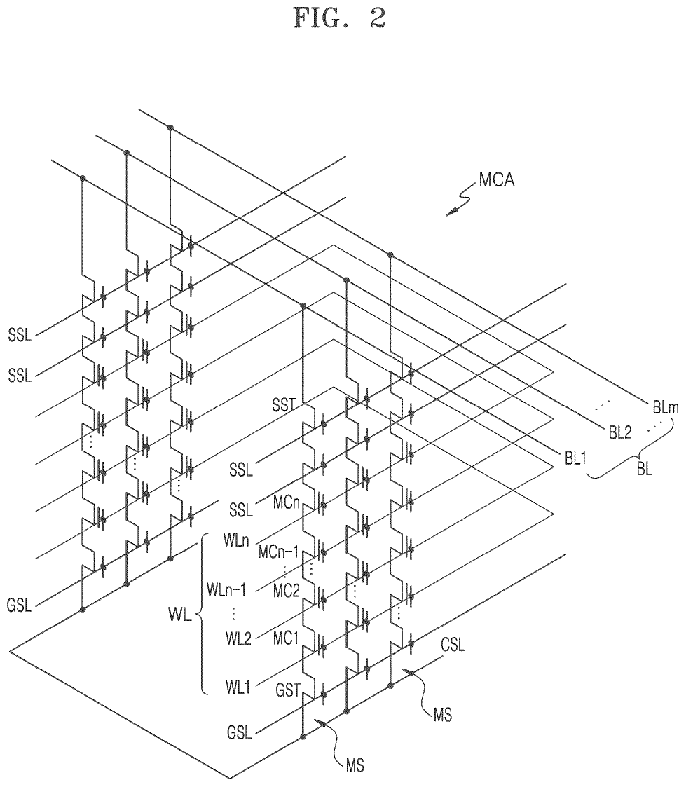

FIG. 2 is an equivalent circuit diagram of a memory cell array of the semiconductor device 10 according to some example embodiments.

Referring to FIG. 2, a memory cell array MCA may include a plurality of memory cell strings MS. The memory cell array MCA may include a plurality of bit lines BL (BL1, BL2, . . . , BLm), a plurality of word lines WL (WL1, WL2, . . . , WLn−1, WLn), at least one string selection line SSL, at least one ground selection line GSL, and a common source line CSL. The plurality of memory cell strings MS may be formed between the plurality of bit lines BL (BL1, BL2, . . . , BLm) and the common source line CSL. Although FIG. 2 illustrates a case where each of the plurality of memory cell strings MS includes two string selection lines SSL, the technical spirit of the inventive concepts are not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn−1, MCn. Drain regions of the string selection transistors SST may be connected to the bit lines BL (BL1, BL2, . . . , BLm), and source regions of the ground selection transistors GST may be connected to the common source line CSL. The common source line CSL may be a region to which source regions of a plurality of ground selection transistors GST are commonly connected.

The string selection transistors SST may be connected to a string selection line SSL, and the ground selection transistors GST may be connected to a ground selection line GSL. The plurality of memory cell transistors MC1, MC2, . . . , MCn−1, MCn may be connected to the plurality of word lines WL (WL1, WL2, . . . , WLn−1, WLn), respectively.

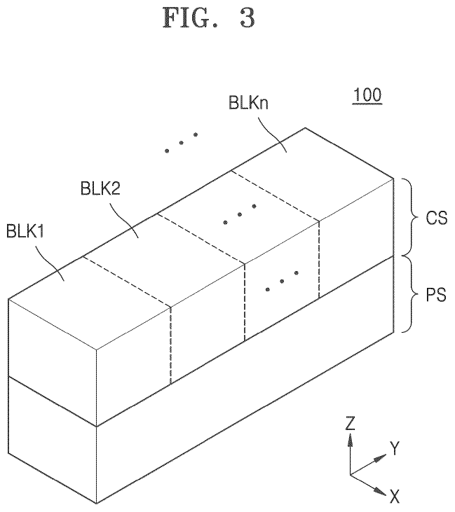

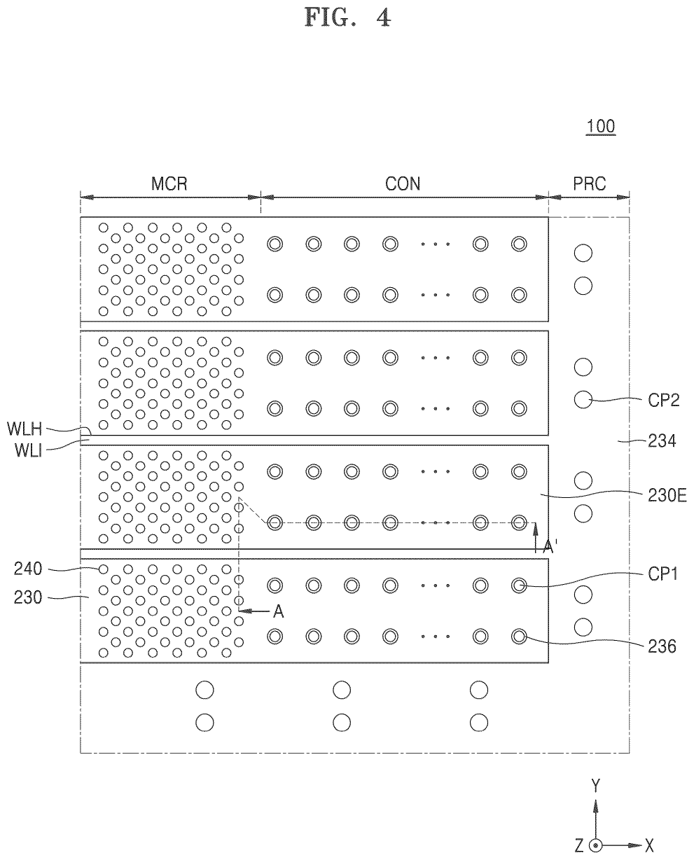

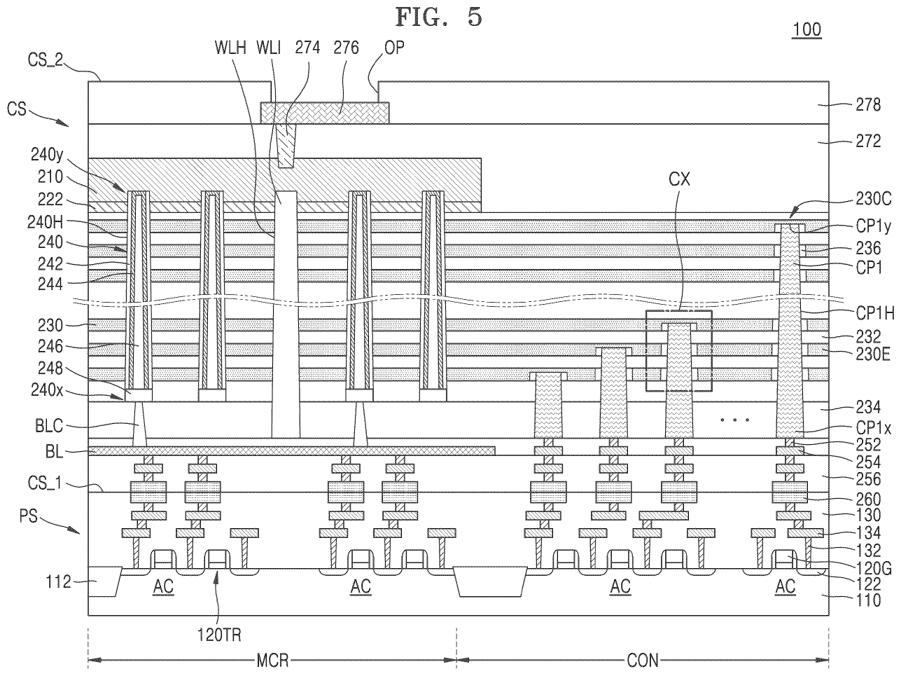

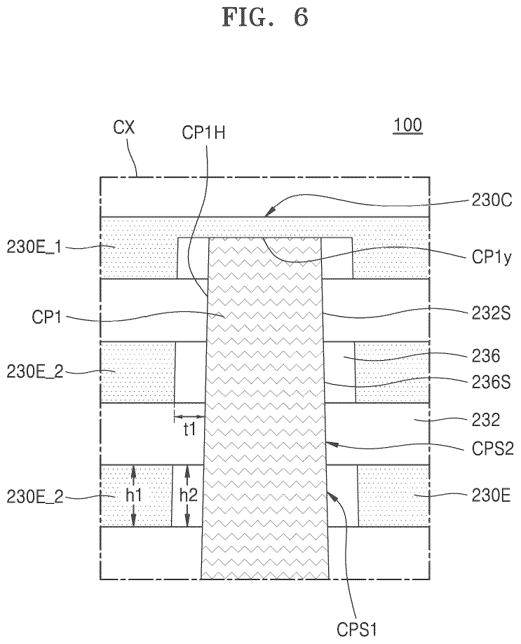

FIG. 3 is a perspective view of a representative structure of a semiconductor device 100 according to some example embodiments. FIG. 4 is a plan view of the semiconductor device 100 of FIG. 3. FIG. 5 is a cross-sectional view of the semiconductor device 100 taken along line A-A′ in FIG. 4. FIG. 6 is an enlarged view of a portion CX of FIG. 5.

Referring to FIGS. 3 through 6, the semiconductor device 100 includes a cell structure CS and a peripheral circuit structure PS overlapping each other in a vertical direction Z. The cell structure CS may include the memory cell array 20 of FIG. 1, and the peripheral circuit structure PS may include the peripheral circuit 30 of FIG. 1.

The cell structure CS may include a plurality of memory cell blocks BLK1, BLK2, through to BLKn. Each of the plurality of memory cell blocks BLK1, BLK2, through to BLKn may include three-dimensionally arranged memory cells.

The peripheral circuit structure PS may include a peripheral circuit transistor 120TR arranged on a substrate 110. In the substrate 110, an active region AC may be defined by an isolation layer 112, and a plurality of peripheral circuit transistors 120TR may be formed on the active region AC. Each of the plurality of peripheral circuit transistors 120TR may include a peripheral circuit gate 120G, and source and drain regions 122 respectively arranged in portions of the substrate 110 on both sides of the peripheral circuit gate 120G.

The substrate 110 may include a semiconductor material, for example, a Group IV semiconductor, a Groups III-V element-containing compound semiconductor, or a Groups II-VI oxide semiconductor. For example, the Group IV semiconductor may include silicon (Si), germanium (Ge), or Si—Ge. The substrate 110 may be a bulk wafer or an epitaxial layer. According to another embodiment, the substrate 110 may include a silicon-on-insulator (SOI) substrate or a germanium-on-insulator (GeOI) substrate.

A plurality of peripheral circuit contacts 132 and a plurality of peripheral circuit wiring layers 134 may be arranged on the upper surface of the substrate 110. An interlayer insulating layer 130 may be arranged on the substrate 110 and cover the plurality of peripheral circuit contacts 132 and the plurality of peripheral circuit wiring layers 134. The plurality of peripheral circuit wiring layers 134 may have a multi-layered structure including a plurality of metal layers arranged on different vertical levels. A connection pad 260 may be disposed in and surrounded by the interlayer insulating layer 130, and the peripheral circuit structure PS and the cell structure CS may be electrically connected to and bonded to each other by the connection pad 260.

The cell structure CS may include a cell region MCR, a connection region CON, and a peripheral circuit connection region PRC. The cell region MCR may be an area where a memory cell block including a plurality of memory cell strings each extending in the vertical direction Z is disposed. In the cell region MCR, a common source layer 210, a plurality of gate electrodes 230, and a channel structure 240 extending in the vertical direction Z by penetrating through the plurality of gate electrodes 230 and connected to the common source layer 210 may be arranged. A plurality of extensions 230E respectively connected to the plurality of gate electrodes 230, and a plurality of cell plugs CP1 each electrically connected to the plurality of extensions 230E may be arranged in the connection region CON. A peripheral plug CP2 extending in the vertical direction Z and electrically connected to the peripheral circuit wiring layer 134 may be disposed in the peripheral circuit connection region PRC.

The cell structure CS may include a first surface CS_1 connected to the peripheral circuit structure PS and a second surface CS_2 opposite to the first surface CS_1. In the drawings, the first surface CS_1 of the cell structure CS is disposed on the lower side of the cell structure CS, and the second surface CS_2 of the cell structure CS is disposed on the upper side of the cell structure CS. For convenience, as shown in the drawings, the expression that an element “A” is at a lower vertical level than an element “B” means that the element “A” is placed closer to the first surface CS_1 of the cell structure CS than the element “B”. Also, the expression that an element “A” is at a higher vertical level than an element “B” means that the element “A” is placed closer to the second surface CS_2 of the cell structure CS than the element “B”.

The gate electrodes 230 may be arranged to be spaced apart from each other in the vertical direction Z in the cell region MCR, and the gate electrodes 230 may be arranged alternately with mold insulating layers 232. The gate electrodes 230 may each extend to the connection region CON, and portions of the gate electrodes 230 disposed in the connection region CON may be referred to as the extensions 230E. The extensions 230E arranged apart from each other in the vertical direction Z may have the same width in a first horizontal direction X.

According to some example embodiments, the gate electrodes 230 may include a metal (such as, tungsten, nickel, cobalt, or tantalum), metal silicide (such as, tungsten silicide, nickel silicide, cobalt silicide, or tantalum silicide), doped silicon, or a combination thereof.

According to some example embodiments, the gate electrodes 230 may correspond to ground selection lines GSL1 through GSL3, word lines WL1 through WL8, and at least one string selection lines SSL1 through SSL3 that constitute memory cell strings MCS11 through MCS33 of FIG. 2. For example, an uppermost gate electrode 230 may function as the ground selection lines GSL1 through GSL3, two lowermost gate electrodes 230 may function as the string selection lines SSL1 through SSL3, and the remaining gate electrodes 230 may function as word lines WL1 through WL8. Accordingly, memory cell strings MS in which a ground selection transistor GST, a string selection transistor SST, and memory cell transistors MC1 through MCn therebetween are serially connected to one another may be provided. According to some example embodiments, at least one of the gate electrodes 230 may function as a dummy word line. However, example embodiments of the inventive concepts are not limited thereto.

A stack isolation insulating layer WLI may be disposed in a stack isolation opening WLH passing through the gate electrodes 230 and the mold insulating layers 232 and extending in the vertical direction. The stack isolation insulating layer WLI may have an upper surface disposed at a vertical level higher than the uppermost gate electrode 230 and may protrude upward from the uppermost gate electrode 230. According to some example embodiments, gate electrodes 230 disposed between a pair of stack isolation openings WLH may constitute one block.

The channel structure 240 may be disposed in a channel hole 240H passing through the gate electrodes 230 and the mold insulating layers 232 and extending in a vertical direction. The channel structure 240 may include a gate insulating layer 242, a channel layer 244, a buried insulating layer 246, and a drain region 248. The gate insulating layer 242, the channel layer 244, and the buried insulating layer 246 may be sequentially arranged on a lateral wall of the channel hole 240H.

The channel structure 240 may include a first end 240x disposed close to the peripheral circuit structure PS, and a second end 240y opposite to the first end 240x. According to some example embodiments, the channel structure 240 may have an inclined sidewall such that the width of the first end 240x is greater than that of the second end 240y.

The drain region 248 electrically connected to the channel layer 244 may be disposed at the first end 240x of the channel structure 240. The drain region 248 may be connected to a bit line contact BLC, and the channel layer 244 may be electrically connected to a bit line BL through the drain region 248 and the bit line contact BLC. At the second end 240y of the channel structure 240, the upper surface of the channel layer 244 may not be covered by the gate insulating layer 242, and the common source layer 210 may be connected to the upper surface of the channel layer 244.

According to some example embodiments, the gate insulating layer 242 may have a structure sequentially including a tunneling dielectric layer, a charge storage layer, and a blocking dielectric layer on the outer sidewall of the channel layer 244. The charge storage layer may be a region where electrons from the channel layer 244 that have passed through the tunneling dielectric layer may be stored and may include silicon nitride, boron nitride, silicon boron nitride, or impurity-doped polysilicon.

According to some example embodiments, the charge storage layer may include a ferroelectric dielectric material. In this case, the charge storage layer may include a metal oxide with ferroelectric material properties. For example, the charge storage layer may include a ferroelectric material capable of storing data through a hysteresis behavior caused by a voltage applied to the charge storage layer. According to some example embodiments, the charge storage layer may include at least one of hafnium oxide, zirconium oxide, and hafnium zirconium oxide.

An etch stop layer 222 may be disposed on the uppermost gate electrode 230 and may include polysilicon. According to some example embodiments, the etch stop layer 222 may be omitted.

The common source layer 210 may be connected to the second end 240y of the channel structure 240 on the etch stop layer 222 and may be conformally formed to cover the upper surface of the stack isolation insulating layer WLI. In a plan view, the common source layer 210 may be disposed on the entire cell region MCR.

According to some example embodiments, the common source layer 210 may include at least one of silicon (Si), germanium (Ge), silicon germanium (SiGe), gallium arsenic (GaAs), indium gallium arsenic (InGaAs), aluminum gallium arsenic (AlGaAs), or a mixture thereof. The common source layer 210 may also include a semiconductor doped with n-type impurities. The common source layer 210 may have a crystal structure including at least one selected from single crystal, amorphous, and polycrystalline. According to some example embodiments, the common source layer 210 may include polysilicon doped with n-type impurities.

Between the stack cover insulating layer 234 and the peripheral circuit structure PS, a connection via 252, a connection wiring layer 254, and an interlayer insulating layer 256 surrounding the connection via 252 and the connection wiring layer 254 may be provided. The connection via 252 and the connection wiring layer 254 may be composed of multiple layers to be arranged at a plurality of vertical levels and may electrically connect the bit line BL, the cell plug CP1, and the peripheral plug CP2 to the peripheral circuit structure PS via the connection pad 260.

The plurality of gate electrodes 230 may each extend in a horizontal direction on the cell region MCR and the connection region CON. The gate electrodes 230 disposed on the connection region CON are referred to as a gate extension 230E. On the connection region CON, a plurality of gate extensions 230E may overlap each other in the vertical direction. For example, the plurality of gate extensions 230E disposed at different vertical levels on the connection region CON may have the same width in the horizontal direction.

The plurality of cell plugs CP1 may pass through the stack cover insulating layer 234, the mold insulating layer 232, and the gate extensions 230E and each extend in the vertical direction Z, on the connection region CON. The plurality of cell plugs CP1 may have different heights in the vertical direction Z. For example, a first cell plug CP1 among the plurality of cell plugs CP1 may have a first height and penetrate one gate electrode. A second cell plug CP1 among plurality of cell plugs CP1 may have a second height greater than the first height and penetrate two gate electrodes. According to some example embodiments, each of the plurality of cell plugs CP1 may have a first end CP1x and a second end CP1y, and the first ends CP1x of the plurality of cell plugs CP1 may be all aligned at the same vertical level and may also be arranged on the same vertical level as the bottom surface of the stack cover insulating layer 234. The second ends CP1y of the plurality of cell plugs CP1 may be disposed on different vertical levels. For example, the second ends CP1y of the plurality of cell plugs CP1 may be located on gate contact surfaces 230C respectively corresponding to the plurality of cell plugs CP1.

According to some example embodiments, respective top surfaces of the plurality of cell plugs CP1 may contact the gate contact surfaces 230C, and thus one cell plug CP1 may be electrically connected to a gate extension 230E corresponding thereto (for example, a first gate electrode extension 230E_1 shown in FIG. 6) via the gate contact surface 230C. According to some example embodiments, respective sidewalls of the plurality of cell plugs CP1 may be surrounded by an insulating spacer 236. For example, a corresponding insulating spacer 236 may be disposed between one cell plug CP1 among the plurality of cell plugs CP1 and each of the plurality of gate extensions 230E.

According to some example embodiments, the top surface of one cell plug CP1 may be electrically connected to a corresponding gate extension 230E (e.g., a first gate electrode extension 230E_1 shown in FIG. 6), whereas the sidewall of the one cell plug CP1 may not be electrically connected to a gate extension 230E (e.g., a second gate electrode extension 230E_2 shown in FIG. 6) disposed at a lower vertical level than the corresponding gate extension 230E. An insulating spacer 236 may be interposed between the gate extension 230E (e.g., the second gate electrode extension 230E_2 shown in FIG. 6) disposed at a lower vertical level than the corresponding gate extension 230E (e.g., the first gate electrode extension 230E_1 shown in FIG. 6) and the sidewall of the one cell plug CP1, and accordingly, the gate extension 230E (e.g., the second gate electrode extension 230E_2 shown in FIG. 6) disposed at a lower vertical level than the corresponding gate extension 230E and the sidewall of the one cell plug CP1 may be insulated from each other. Herein, the gate extension 230E (e.g., the second gate electrode extension 230E_2 shown in FIG. 6) disposed at a lower vertical level than the corresponding gate extension 230E may refer to the gate extension 230E disposed closer to the peripheral circuit structure PS than the corresponding gate extension 230E is.

As shown in FIG. 6, each of the plurality of cell plugs CP1 may have a plurality of first side surface portions CPS1 and a plurality of second side surface portions CPS2 alternating with each other (e.g., one cell plug CP1 may have a plurality of first side surface portions CPS1 and a plurality of second side surface portions CPS2 alternating with each other), and the plurality of first side surface portions CPS1 may be in contact with respective sidewalls 236S of a plurality of insulating spacers 236, and the plurality of second side surface portions CPS2 may be in contact with respective sidewalls 232S of a plurality of mold insulating layers 232. The sidewalls 232S of the plurality of mold insulating layers 232 and the sidewalls 236S of the plurality of insulating spacers 236 may be aligned with each other and continuously connected to each other, and the respective sidewalls of the plurality of cell plugs CP1 may also have a profile extending substantially vertically.

According to some example embodiments, the cell plug CP1 may include a metal (such as, tungsten, nickel, cobalt, or tantalum), metal silicide (such as, tungsten silicide, nickel silicide, cobalt silicide, or tantalum silicide), doped silicon, or a combination thereof. According to some example embodiments, the insulating spacer 236 may include silicon oxide. According to some example embodiments, the insulating spacer 236 may include silicon oxide containing a small amount (for example, 5 atomic percent (at %) or less, such as about or exactly 5 at % to about or exactly 0 at %) of any one of chlorine, fluorine, and bromine.

According to some example embodiments, the insulating spacers 236 may each have a ring-shaped horizontal cross-section, and a thickness t1 of each of the insulating spacers 236 in the horizontal direction may range from 10 to 100 angstroms. As shown in FIG. 6, respective upper surfaces of the insulating spacers 236 may be arranged on the same level as respective upper surfaces of gate extensions 230E (e.g., the second gate electrode extensions 230E_2) facing the insulating spacers 236, and respective bottom surfaces of each of the insulating spacers 236 may be arranged on the same level as respective bottom surfaces of the gate extensions 230E (for example, the second gate electrode extensions 230E_2) facing the insulating spacers 236. A height h2 of the insulating spacer 236 in the vertical direction may be equal to a height h1 of the gate extension 230E (e.g., the second gate electrode extension 230E_2) in the vertical direction.

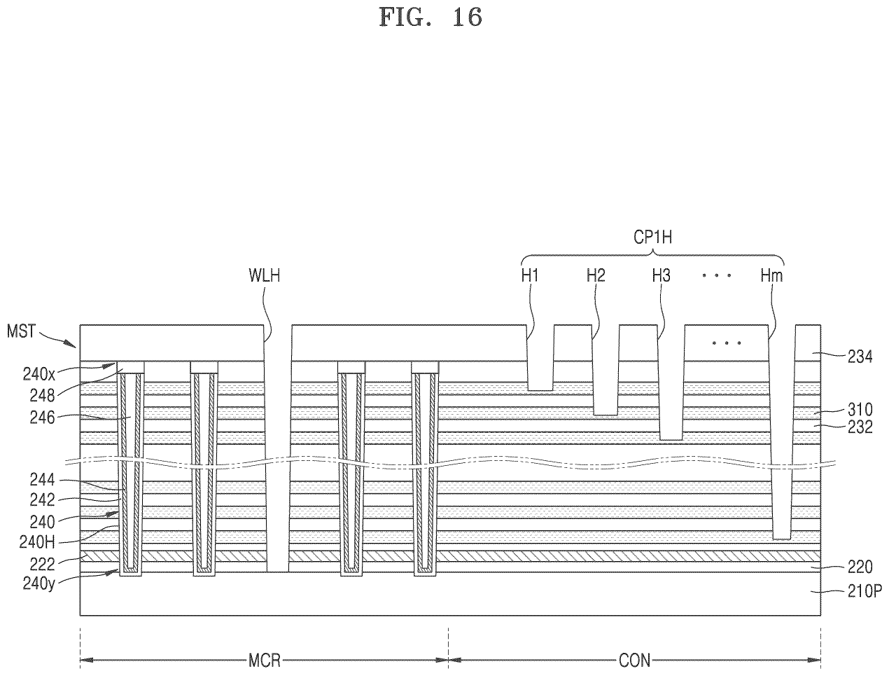

According to some example embodiments, a cell plug hole CP1H passing through a mold stack MST (see FIG. 16) and extending in the vertical direction may be formed, a recess area R1 may be formed by performing a recess process on the inner wall of the cell plug hole CP1H, and the insulating spacer 236 may be formed within the recess area R1. Accordingly, the width of the second end CP1y of the cell plug CP1 may not be reduced, and a sufficient contact area may be maintained between the second end CP1y of the cell plug CP1 and the contact surface 230C of the gate extension 230E.

An upper insulating layer 272 may be arranged on the common source layer 210. The upper insulating layer 272 may have a flat upper surface throughout the cell region MCR and connection region CON. A common source contact 274 passing through the upper insulating layer 272 and connected to the common source layer 210 may be disposed, and a rear wiring layer 276 electrically connected to the common source contact 274 may be disposed on the upper insulating layer 272.

A passivation layer 278 covering the rear wiring layer 276 may be disposed on the upper insulating layer 272. The passivation layer 278 may include an opening OP exposing the upper surface of the rear wiring layer 276.

Although not shown in the drawings, dummy channels (not shown) each extending in the vertical direction Z to penetrate through the gate electrodes 230 and the mold insulating layers 232 may be further formed in the connection region CON. The dummy channels may be formed to prevent leaning or bending of the gate electrodes 230 during the manufacture of the semiconductor device 100 and to secure structural stability of the gate electrodes 230.

In general, a cell plug lands on a stair-shaped pad portion connected to a gate electrode in a connection region. However, as the number of layers of the gate electrode increases, the area occupied by the stair-shaped pad portion increases. To address this problem, a stair-free contact structure has been proposed that forms a cell plug hole penetrating the gate electrode and forms an insulating liner on the sidewall of the cell plug hole, instead of forming a stair-shaped pad portion. However, in the stair-free contact structure, because the aspect ratio of the cell plug hole is large, defects occur in a process of etching a bottom portion of the insulating liner, so that sufficient contact between the cell plug and the gate electrode is not secured.

According to the above-described embodiments, the cell plug CP1 may be formed to penetrate through the gate extensions 230E, and the insulating spacer 236 may be interposed between each of the gate extensions 230E and the sidewall of the cell plug CP1. Accordingly, the semiconductor device 100 has a stair-free contact structure, and thus the area occupied by the connection region CON may be minimized or reduced.

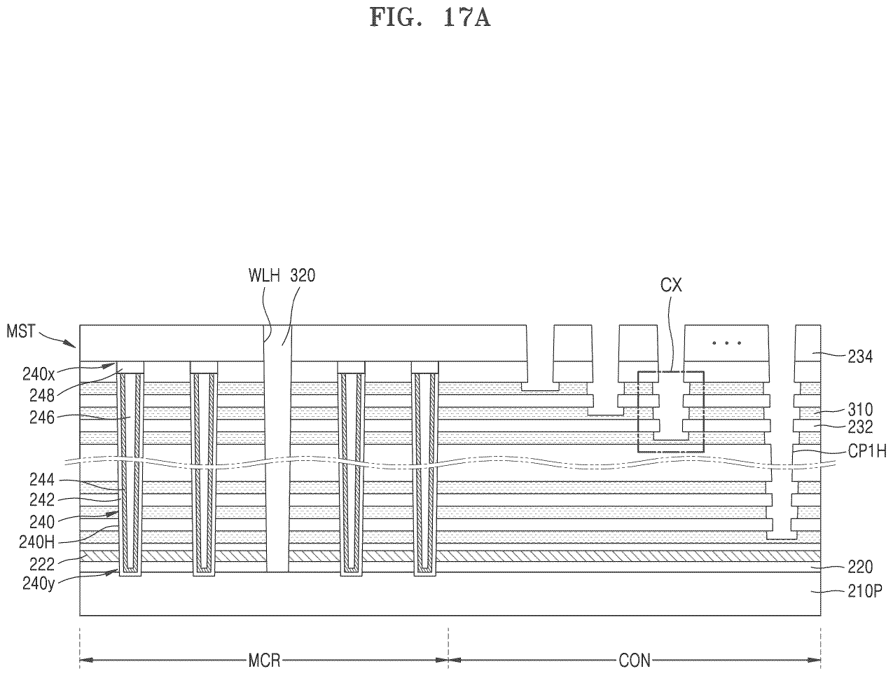

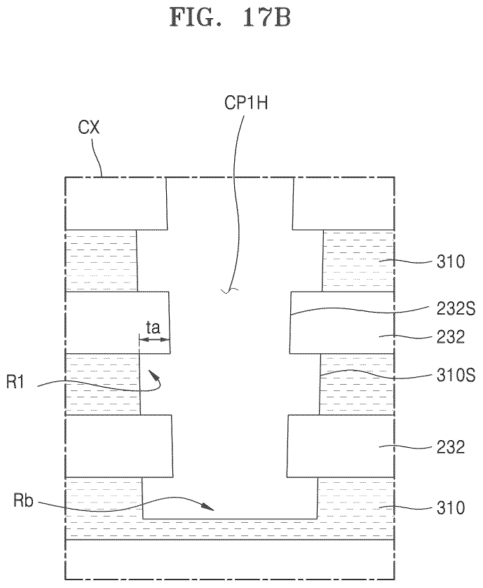

In addition, a recessed region R1 (see FIG. 17B) may be formed by removing a part of a sacrificial layer 310 (see FIG. 17B) exposed on the inner wall of the cell plug hole CP1H, and the insulating spacer 236 may be formed within the recessed region R1, and thus the width of the second end CP1y of the cell plug CP1 may not decrease, and a sufficient contact area may be secured between the second end CP1y of the cell plug CP1 and the contact surface 230C of the gate extension 230E. Therefore, the semiconductor device 100 may have good electrical characteristics.

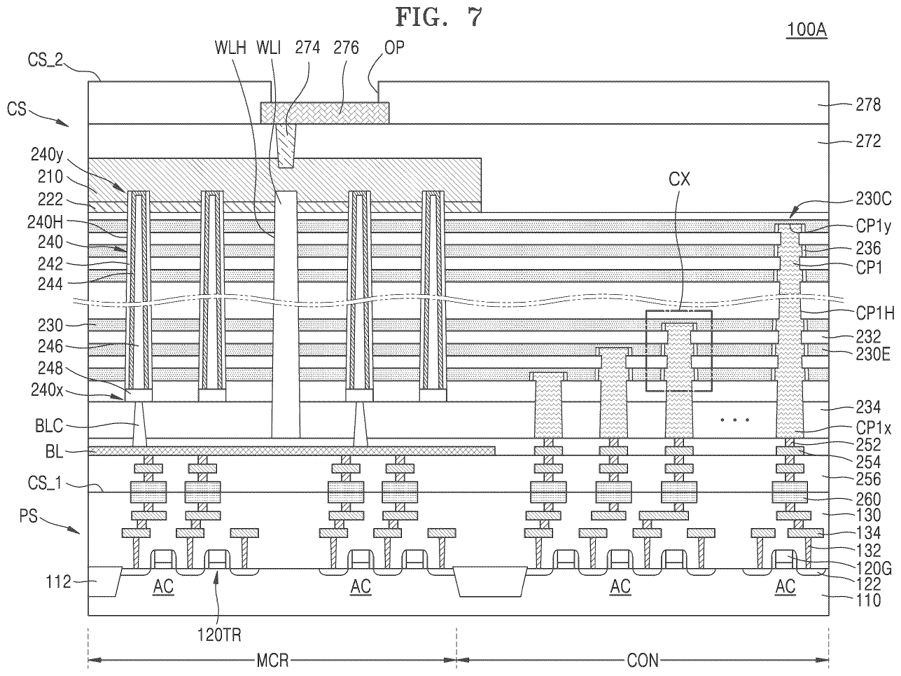

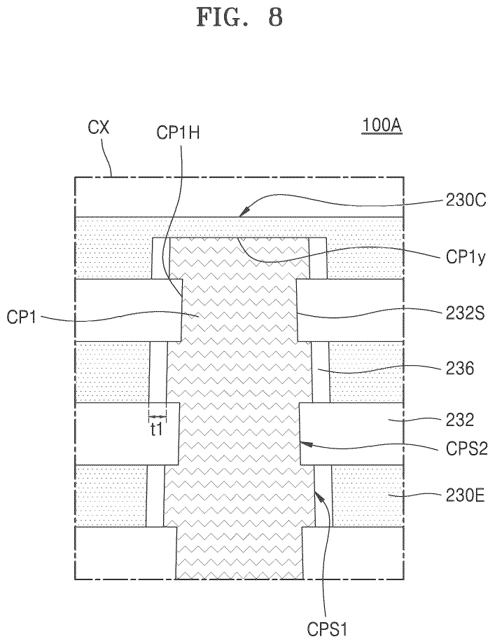

FIG. 7 is a cross-sectional view of a semiconductor device 100A according to some example embodiments. FIG. 8 is an enlarged view of a portion CX of FIG. 7. Reference numerals in FIGS. 7 and 8 that are the same as those in FIGS. 1 through 6 denote the same elements.

Referring to FIGS. 7 and 8, each of the plurality of cell plugs CP1 may have a plurality of first side surface portions CPS1 and a plurality of second side surface portions CPS2 alternating with each other (e.g., one cell plug CP1 may have a plurality of first side surface portions CPS1 and a plurality of second side surface portions CPS2 alternating with each other), and the plurality of first side surface portions CPS1 may be in contact with respective sidewalls 236S of a plurality of insulating spacers 236, and the plurality of second side surface portions CPS2 may be in contact with respective sidewalls 232S of a plurality of mold insulating layers 232.

As shown in FIG. 8, a thickness t1 of the insulating spacer 236 in the horizontal direction may be formed to be relatively small, and accordingly, the first side surface portions CPS1 surrounded by the sidewalls 236S of the plurality of insulating spacers 236 may protrude more outward than the second side surface portions CPS2 surrounded by the sidewalls 232S of the plurality of mold insulating layers 232.

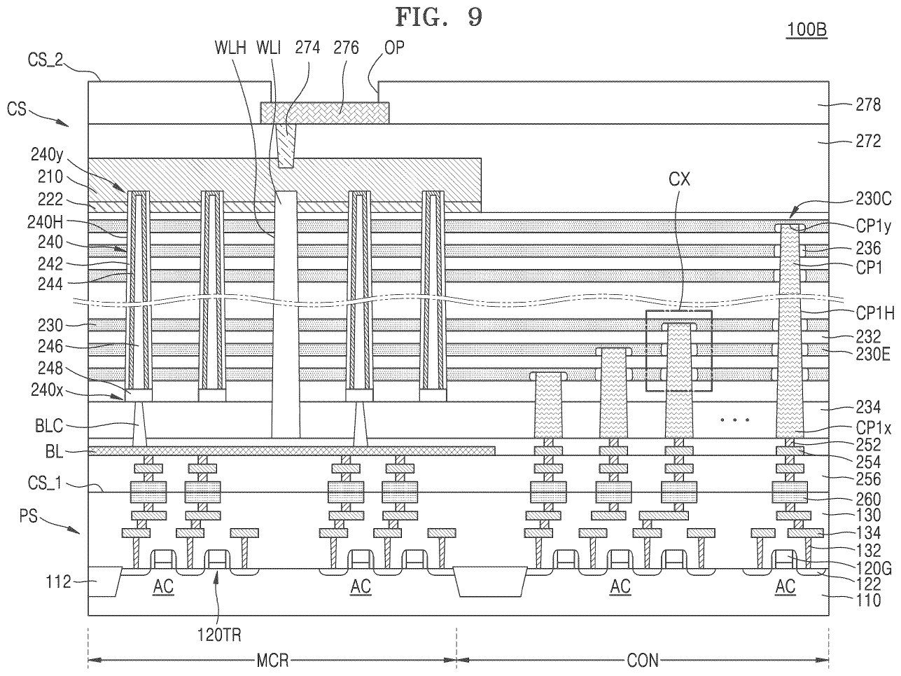

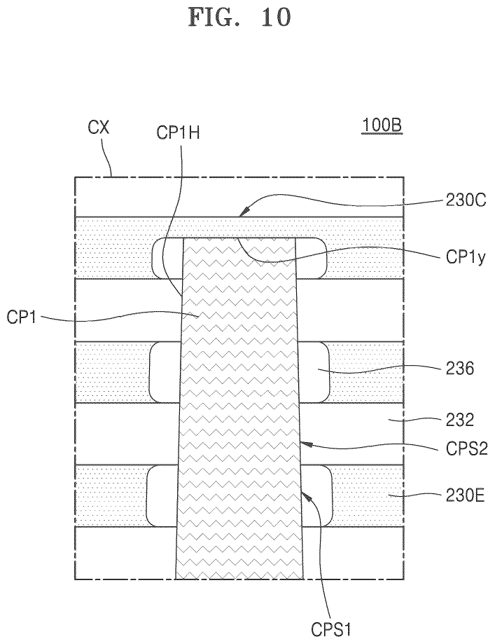

FIG. 9 is a cross-sectional view of a semiconductor device 100B according to some example embodiments. FIG. 10 is an enlarged view of a portion CX of FIG. 9. Reference numerals in FIGS. 9 and 10 that are the same as those in FIGS. 1 through 6 denote the same elements.

Referring to FIGS. 9 and 10, side surfaces of a plurality of insulating spacers 236 that are respectively in contact with the gate extensions 230E may be curved. According to some example embodiments, the recess region R1 (see FIG. 17B) may be formed by removing the sacrificial layer 310 (see FIG. 17B) exposed on the inner wall of the cell plug hole CP1H, and an insulating spacer 236 may be formed within the recess region R1. In a process of forming the recess region R1, the recess region R1 may be formed to have a rounded curved sidewall. In this case, a side surface of each of the insulating spacers 236 that is in contact with each of the gate extensions 230E may be curved.

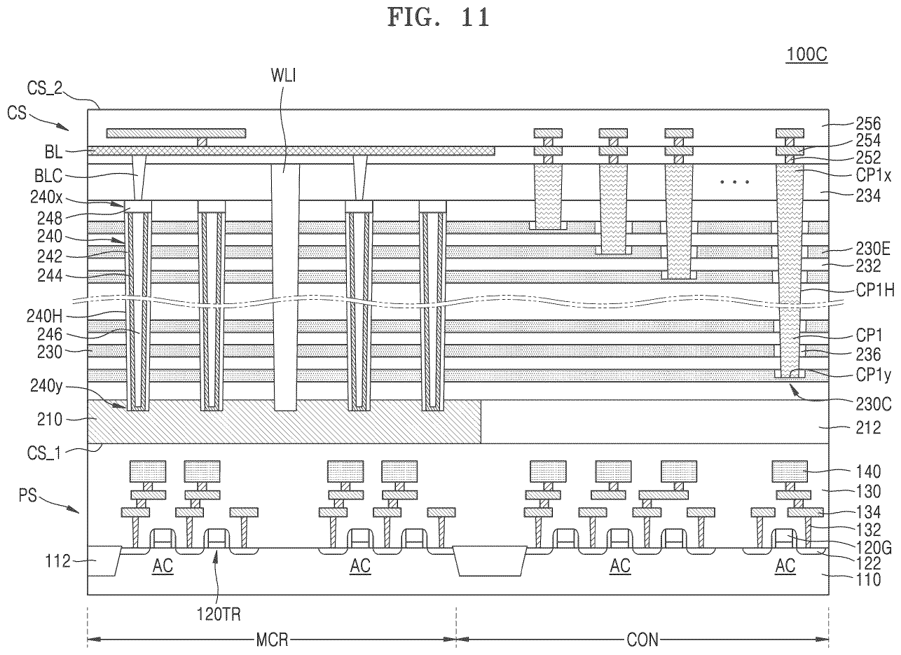

FIG. 11 is a cross-sectional view of a semiconductor device 100C according to some example embodiments.

Referring to FIG. 11, a common source layer 210 may be disposed on the peripheral circuit structure PS in the cell region MCR, and a buried insulating layer 212 may be disposed on the peripheral circuit structure PS in the connection region CON. A plurality of gate electrodes 230 and a plurality of mold insulating layers 232 may be disposed on the common source layer 210 and the buried insulating layer 212.

The channel structure 240 may have an inclined sidewall such that the width of the first end 240x is greater than that of the second end 240y. The second end 240y of the channel structure 240 may be disposed close to the peripheral circuit structure PS, and the first end 240x of the channel structure 240 may be disposed far from the peripheral circuit structure PS.

According to some example embodiments, each of the plurality of cell plugs CP1 may have a first end CP1x and a second end CP1y, and the first ends CP1x of the plurality of cell plugs CP1 may be all aligned at the same vertical level and may also be arranged on the same vertical level as the upper surface of the stack cover insulating layer 234. The second ends CP1y of the plurality of cell plugs CP1 may be disposed at different vertical levels. The second ends CP1y of the plurality of cell plugs CP1 may be disposed close to the peripheral circuit structure PS, and the first ends CP1x of the plurality of cell plugs CP1 may be disposed far from the peripheral circuit structure PS.

The peripheral circuit structure PS may include a landing pad 140, and a peripheral plug CP2 (see FIG. 4) extending in the vertical direction Z may be electrically connected to the landing pad 140.

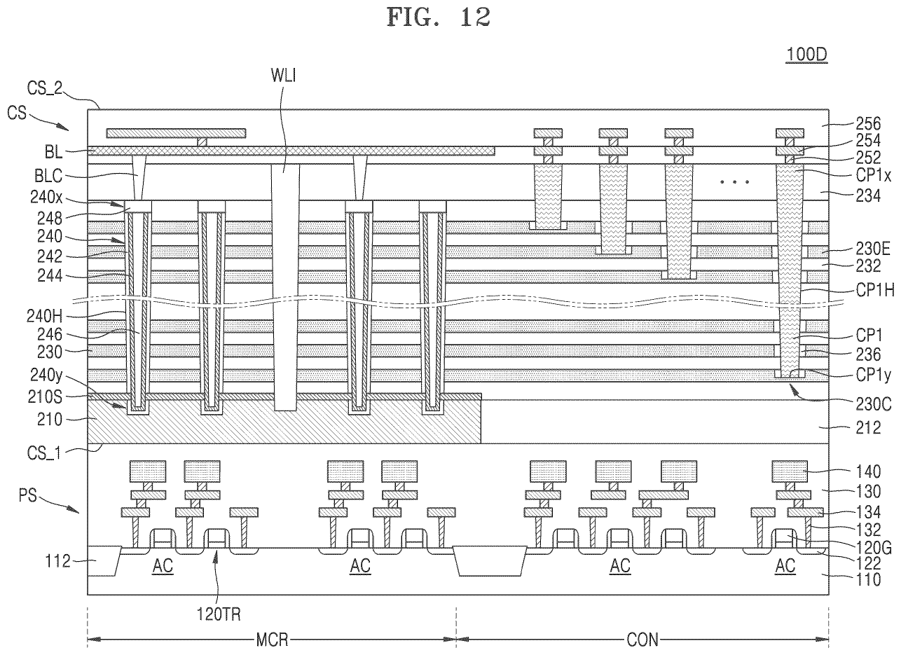

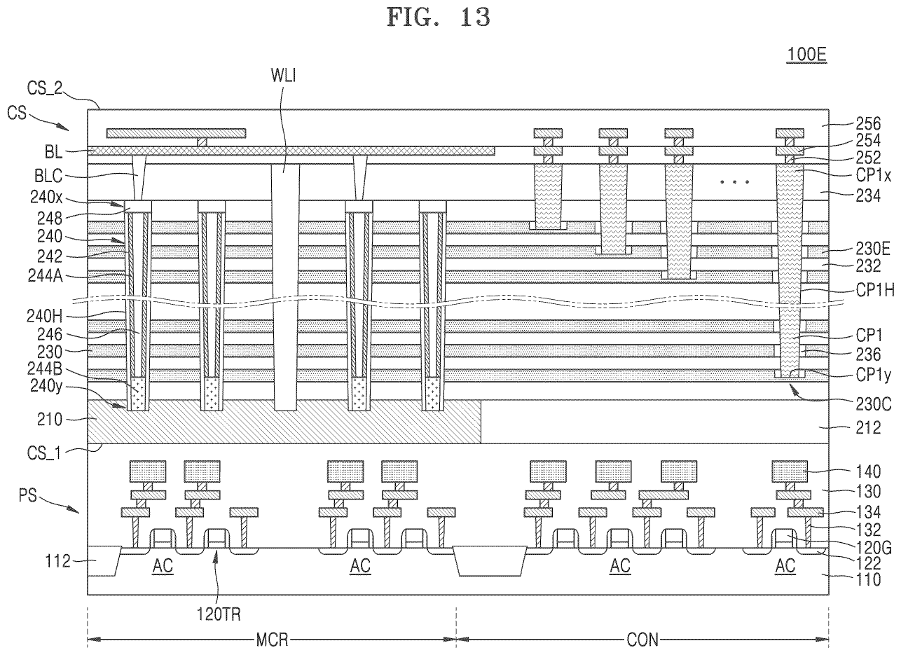

FIG. 12 is a cross-sectional view of a semiconductor device 100D according to some example embodiments.

Referring to FIG. 12, a horizontal semiconductor layer 210S may be disposed on a common source layer 210. According to some example embodiments, the horizontal semiconductor layer 210S may include polysilicon doped with impurities or undoped polysilicon. The horizontal semiconductor layer 210S may function as a portion of a common source region that connects the common source layer 210 to a channel layer 244.

The bottom surface of the channel layer 244 may be disposed on a gate insulating layer 242 and does not directly contact the common source layer 210, and the bottom sidewall of the channel layer 244 may be surrounded by the horizontal semiconductor layer 210S.

FIG. 13 is a cross-sectional view of a semiconductor device 100E according to some example embodiments.

Referring to FIG. 13, a channel structure 240 may include a gate insulating layer 242, a channel layer 244A, a buried insulating layer 246, and a drain region 248 and may further include a contact semiconductor layer 244B disposed in a bottom portion of a channel hole 240H. The channel layer 244A may not directly contact the common source layer 210, and the channel layer 244A may be electrically connected to the common source layer 210 through the contact semiconductor layer 244B. According to some example embodiments, the contact semiconductor layer 244B may include a silicon layer formed by selective epitaxy growth (SEG) by using the common source layer 210 arranged on the bottom portion of the channel hole 240H as a seed layer.

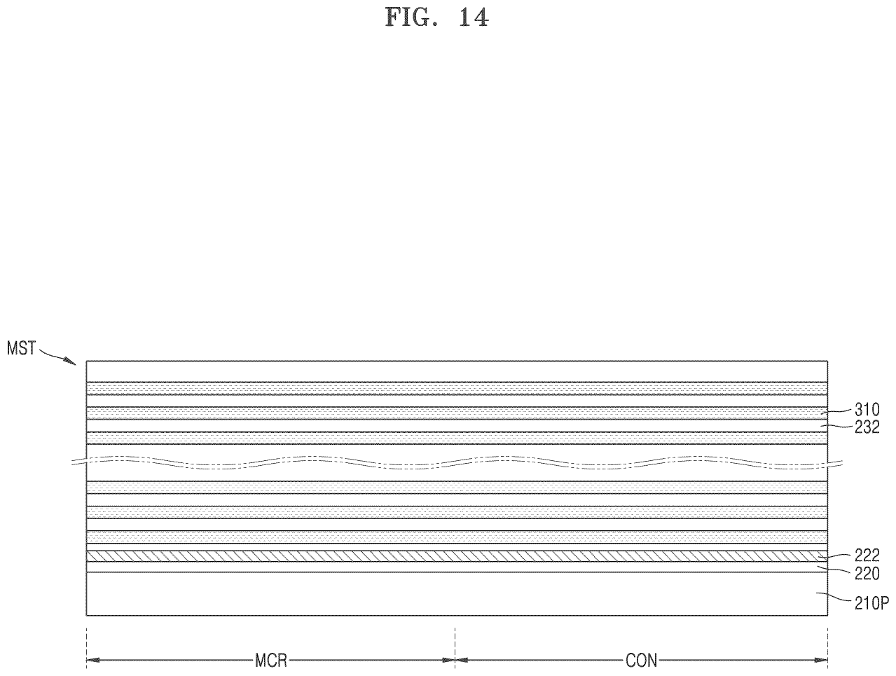

FIGS. 14 through 30 are cross-sectional views illustrating a method of manufacturing the semiconductor device 100, according to some example embodiments. In detail, FIGS. 14 through 17A, 18A, 19A, 20 through 22, 23A, 24A, and 25 through 30 are cross-sectional views corresponding to cross-sections taken along line A-A′ of FIG. 4, and FIGS. 17B, 18B, 19B, 23B, and 24B are enlarged views of CX portions of FIGS. 17A, 18A, 19A, 23A, and 24A.

Referring to FIG. 14, a buffer insulating layer 220 may be formed on a cell substrate 210P, and an etch stop layer 222 may be formed on the buffer insulating layer 220.

According to some example embodiments, the cell substrate 210P may include at least one of silicon (Si), germanium (Ge), silicon germanium (SiGe), gallium arsenic (GaAs), indium gallium arsenic (InGaAs), aluminum gallium arsenic (AlGaAs), or a mixture thereof. The buffer insulating layer 220 may be formed using silicon oxide. According to some example embodiments, the etch stop layer 222 may be formed using polysilicon.

Referring to FIG. 14, the mold stack MST may be formed by alternately forming sacrificial layers 310 and mold insulating layers 232 on the etch stop layer 222 in the cell region MCR and connection region CON. According to some example embodiments, the sacrificial layers 310 and the mold insulating layers 232 may be formed using materials having etch selectivities to each other. For example, the sacrificial layers 310 may include silicon nitride, and the mold insulating layers 232 may include silicon oxide.

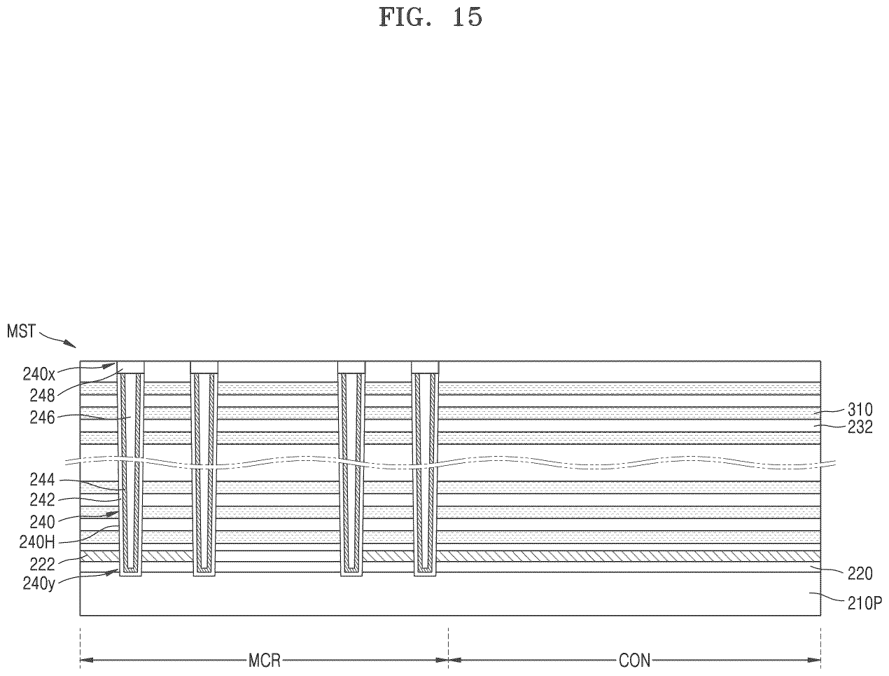

Referring to FIG. 15, a channel structure 240 extending in the vertical direction Z to penetrate through the mold stack MST may be formed in the cell region MCR.

According to some example embodiments, in a process of forming the channel structure 240, a channel hole 240H penetrating through the mold stack MST may be formed in the cell region MCR, a gate insulating layer 242, a channel layer 244, and a buried insulating layer 246 may be sequentially formed on the inner wall of the channel hole 240H, and a drain region 248 may be formed at the entrance of the channel hole 240H.

According to some example embodiments, the channel hole 240H may extend in the vertical direction Z to penetrate through the mold stack MST, the etch stop layer 222, and the buffer insulating layer 220, and the upper surface of the cell substrate 210P may be exposed at the bottom portion of the channel hole 240H.

The channel structure 240 may have a first end 240x and a second end 240y opposite thereto, and the first end 240x may be adjacent to the upper surface of the mold stack MST or may be on the same level as the upper surface of the mold stack MST. The second end 240y of the channel structure 240 may be disposed in contact with the upper surface of the cell substrate 210P, or may be disposed on a vertical level lower than the upper surface of the cell substrate 210P. According to some example embodiments, a horizontal width of the first end 240x of the channel structure 240 may be greater than a horizontal width of the second end 240y of the channel structure 240.

Referring to FIG. 16, a stack cover insulating layer 234 may be formed on the upper surface of the mold stack MST. The stack cover insulating layer 234 may cover the entire upper surface of the mold stack MST on the cell region MCR and the connection region CON. The stack cover insulating layer 234 may have flat top and bottom surfaces over the cell region MCR and the connection region CON and may have a constant thickness over the cell region MCR and the connection region CON.

Thereafter, a stack isolation opening WLH extending in the vertical direction Z to penetrate through the mold stack MST and the stack cover insulating layer 234 is formed in the cell region MCR and connection region CON. The stack isolation opening WLH may extend in the first horizontal direction X (see FIG. 4) in the cell region MCR and the connection region CON.

According to some example embodiments, a dummy channel hole extending in the vertical direction Z to penetrate through the mold stack MST may be formed in the connection region CON. According to some example embodiments, a process of forming the dummy channel hole may be performed simultaneously with an etching process of forming the stack isolation opening WLH. According to some example embodiments, the process of forming the dummy channel hole may be performed simultaneously with an etching process of forming the channel structure 240.

A plurality of cell plug holes CP1H each extending in the vertical direction Z may be formed by removing the stack cover insulating layer 234 and a portion of the mold stack MST on the connection region CON. The plurality of cell plug holes CP1H may have different heights in the vertical direction Z. The plurality of cell plug holes CP1H may have different heights to expose the upper surfaces of sacrificial layer 310 corresponding thereto among the plurality of sacrificial layers 310.

For example, the cell plug hole CP1H may include a first hole H1 exposing the upper surface of an uppermost sacrificial layer 310, a second hole H2 exposing the upper surface of a sacrificial layer 310 immediately below the uppermost sacrificial layer 310 (e.g., a second hole H2 exposing the upper surface of a second uppermost sacrificial layer 310), a third hole H3 exposing the upper surface of a sacrificial layer 310 positioned third from the upper surface of the mold stack MST, through to an m-th hole Hm exposing the upper surface of a sacrificial layer 310 positioned m-th from the upper surface of the mold stack MST.

Referring to FIGS. 17A and 17B, a protective layer 320 may be formed within the stack isolation opening WLH. Thereafter, a recess process may be performed to remove a portion of the sacrificial layer 310 exposed via the inner walls of the plurality of cell plug holes CP1H.

According to some example embodiments, the recess process may be a process of removing a sidewall portion of the sacrificial layer 310 exposed via the sidewalls of the plurality of cell plug holes CP1H by a predetermined (or, alternatively, desired or selected) thickness, and, in the recess process, the portion of the sacrificial layer 310 exposed via the sidewalls of the plurality of cell plug holes CP1H may also be removed by a thickness similar to or equal to the predetermined (or, alternatively, desired or selected) thickness. According to some example embodiments, the recess process may be a dry etching process or wet etching process using an etchant containing phosphoric acid.

As the sidewall portion of the sacrificial layer 310 exposed via the sidewalls of the plurality of cell plug holes CP1H is removed through the recess process, a sidewall 310S of the sacrificial layer 310 may recede, sink, or be recessed more inward than a side wall 232S of the mold insulating layer 232. Accordingly, the recess region R1 may be defined in a space between two mold insulating layers 232 adjacent to each other in the vertical direction Z and between sidewalls 310S of the sacrificial layer 310 (for example, in a space from which a portion of the sacrificial layer 310 has been removed by the recess process). A horizontal distance from the sidewall 232S of the mold insulating layer 232 to the sidewall 310S of the sacrificial layer 310 may be defined as a width ta of the recess region R1 in the horizontal direction.

A portion of the sacrificial layer 310 exposed via the bottom portion of each of the plurality of cell plug holes CP1H may be removed, and thus a bottom recess region Rb may be defined in the bottom portion of each of the plurality of cell plug holes CP1H. The upper surface of the sacrificial layer 310 exposed via the bottom recess region Rb may have a relatively flat level, and the width of the bottom recess region Rb in the horizontal direction may be greater than the width of the cell plug hole CP1H in the horizontal direction at the same level as the upper surface of the mold insulating layer 232 disposed over the bottom recess region Rb.

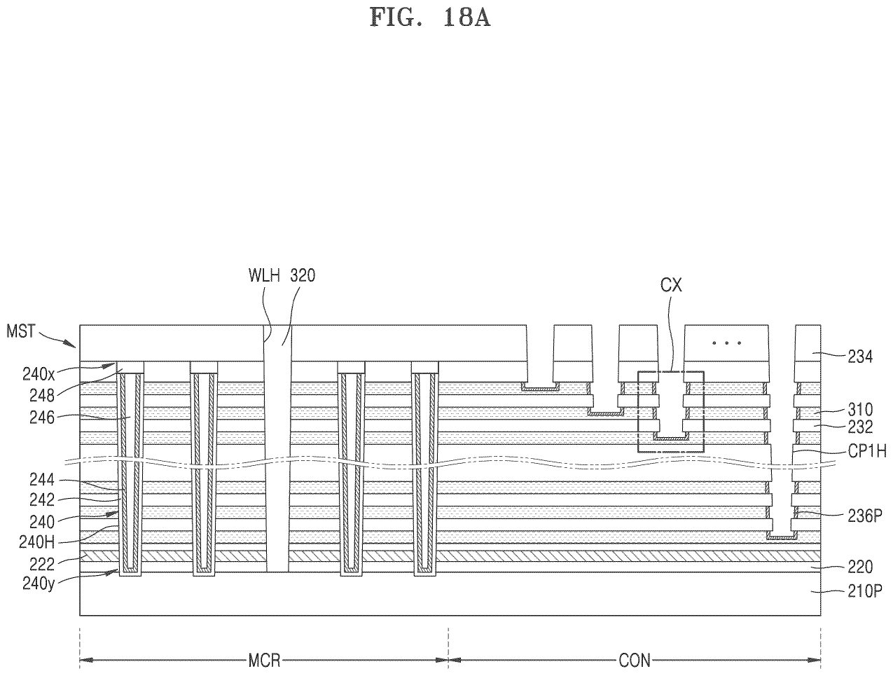

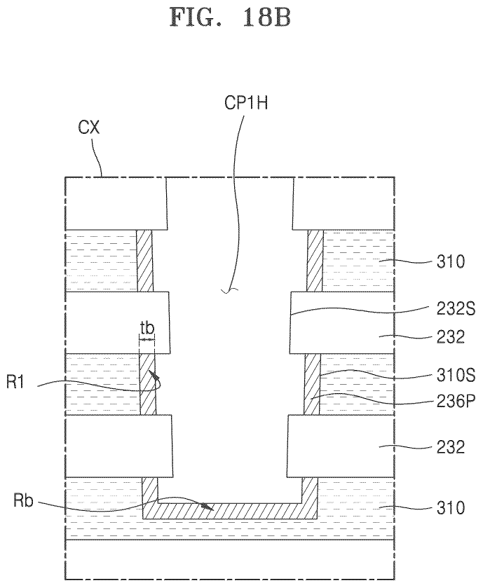

Referring to FIGS. 18A and 18B, a silicon layer 236P may be formed on the exposed surface of the sacrificial layer 310 within the plurality of cell plug holes CP1H. The silicon layer 236P may be disposed on the sidewall of the sacrificial layer 310 and the upper surface of the sacrificial layer 310 in the recess region R1.

For example, a process of forming the silicon layer 236P may be a selective deposition process. The silicon layer 236P is hardly formed or is formed only slightly on the sidewall 232S of the mold insulating layer 232 within the plurality of cell plug holes CP1H, whereas the silicon layer 236P may be formed on the sidewall 310S of the sacrificial layer 310 within the plurality of cell plug holes CP1H at a relatively high deposition rate.

According to some example embodiments, the selective deposition process may include a pretreatment operation and a silicon precursor supply operation.

In the pretreatment operation, the surface characteristics of the inner walls of the plurality of cell plug holes CP1H may be changed by supplying a gas containing halogen onto the inner walls of the plurality of cell plug holes CP1H. For example, the halogen-containing gas supplied onto the inner walls of the plurality of cell plug holes CP1H in the pretreatment operation may include any one of chlorine, fluorine, and bromine. For example, the halogen-containing gas may include any one of hydrogen fluoride (HF), hydrogen chloride (HCl), and hydrogen bromide (HBr).

In the silicon precursor supply operation, a silicon precursor may be supplied onto the inner walls of the plurality of cell plug holes CP1H and is hardly or slightly adsorbed on the sidewall 232S of the mold insulating layer 232, whereas a relatively large amount of silicon precursor may be adsorbed on the sidewall 310S of the sacrificial layer 310. The silicon precursor supply operation may be performed alternately with a subsequent purge operation and may be performed repeatedly multiple times until a silicon layer 236P of a desired thickness is formed on the exposed surface of the sacrificial layer 310.

According to some example embodiments, a small amount of halogen-containing gas may remain on the exposed surface of the sacrificial layer 310 in the pretreatment operation, and, in this case, the silicon layer 236P may contain a small amount of a halogen element therein. For example, the silicon layer 236P may include silicon containing a small amount (for example, 10 at % or less, such as about or exactly 10 at % to about or exactly 0 at %) of any one element among chlorine, fluorine, and bromine.

According to some example embodiments, the silicon layer 236P may have a first thickness tb, and the first thickness tb of the silicon layer 236P may be in a range of about or exactly 30% to about or exactly 70% of the width ta of the recess region R1 in the horizontal direction. According to some example embodiments, the first thickness tb of the silicon layer 236P may be about or exactly 50% of the width ta of the recess region R1 in the horizontal direction.

According to some example embodiments, because the first thickness tb of the silicon layer 236P ranges from about or exactly 30% to about or exactly 70% of the width ta of the recess region R1 in the horizontal direction, the silicon layer 236P may not completely fill the inside of the recess region R1, and, as shown in FIG. 18B, the sidewall of the silicon layer 236P may recede, sink, or be recessed more inward than the sidewall 232S of the mold insulating layer 232.

According to some example embodiments, a plurality of silicon layers 236P may be arranged to be spaced apart from each other in the vertical direction Z within one cell plug hole CP1H, and the plurality of silicon layers 236P may be disposed to vertically overlap respective portions of a plurality of mold insulating layers 232.

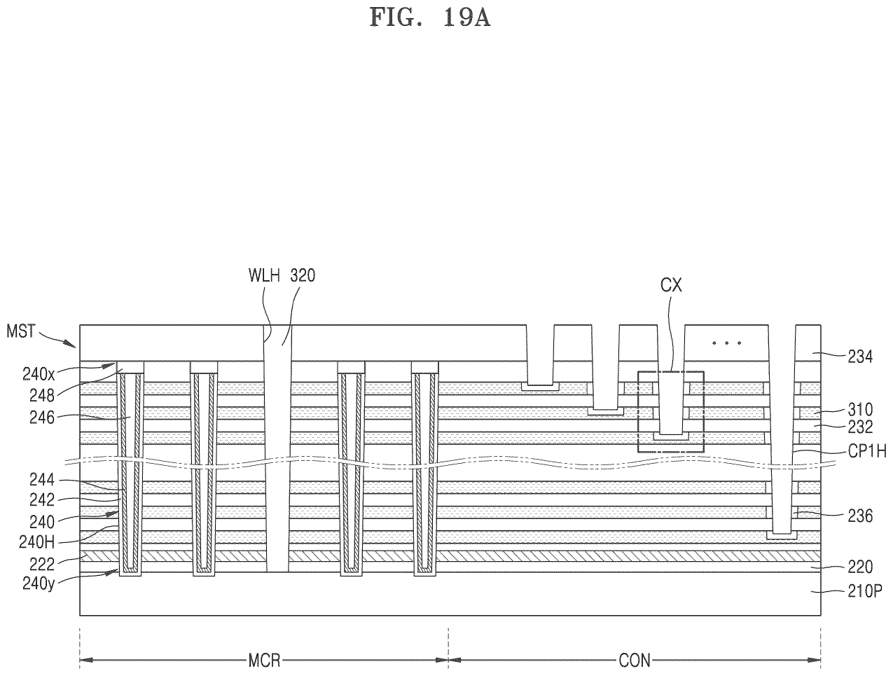

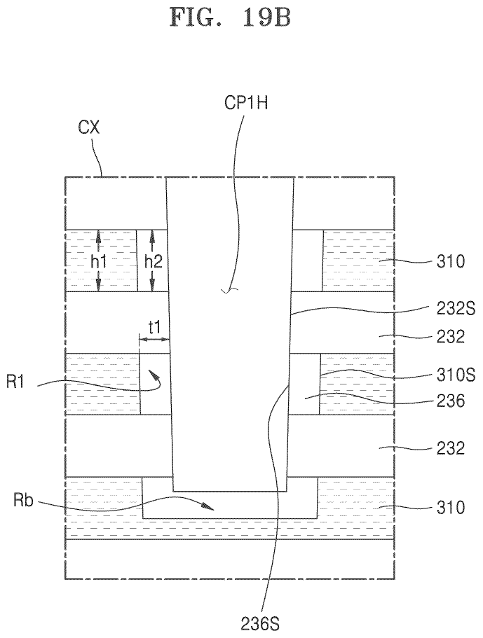

Referring to FIGS. 19A and 19B, the insulating spacer 236 may be formed from the silicon layer 236P through an oxidation process.

According to some example embodiments, the oxidation process for forming the insulating spacer 236 may include, but is not limited to, a thermal oxidation process, a dry oxidation process, a wet oxidation process, a plasma-assisted oxidation process, etc.

According to some example embodiments, silicon atoms in the silicon layer 236P may be converted into silicon oxide by the oxidation process, and accordingly, the insulating spacer 236 may include silicon oxide. According to some example embodiments, the insulating spacer 236 may include silicon oxide containing a small amount (for example, 5 at % or less, such as about or exactly 5 at % to about or exactly 0 at %) of any one of chlorine, fluorine, and bromine.

According to some example embodiments, when the silicon atoms in the silicon layer 236P are converted to silicon oxide by the oxidation process, the silicon oxide may have a larger volume than silicon, and thus the thickness t1 of the insulating spacer 236 in the horizontal direction may be similar to or equal to the width ta of the recess region R1 in the horizontal direction.

According to some example embodiments, a plurality of insulating spacers 236 each having a ring shape may be arranged to be spaced apart from each other in the vertical direction Z within one cell plug hole CP1H. The plurality of insulating spacers 236 may be arranged to vertically overlap the respective portions of the plurality of mold insulating layers 232, and the sidewalls 236S of the plurality of insulating spacers 236 may be aligned with the plurality of mold insulating layers 232 and thus continuously connected to the sidewalls 232S of the plurality of mold insulating layers 232.

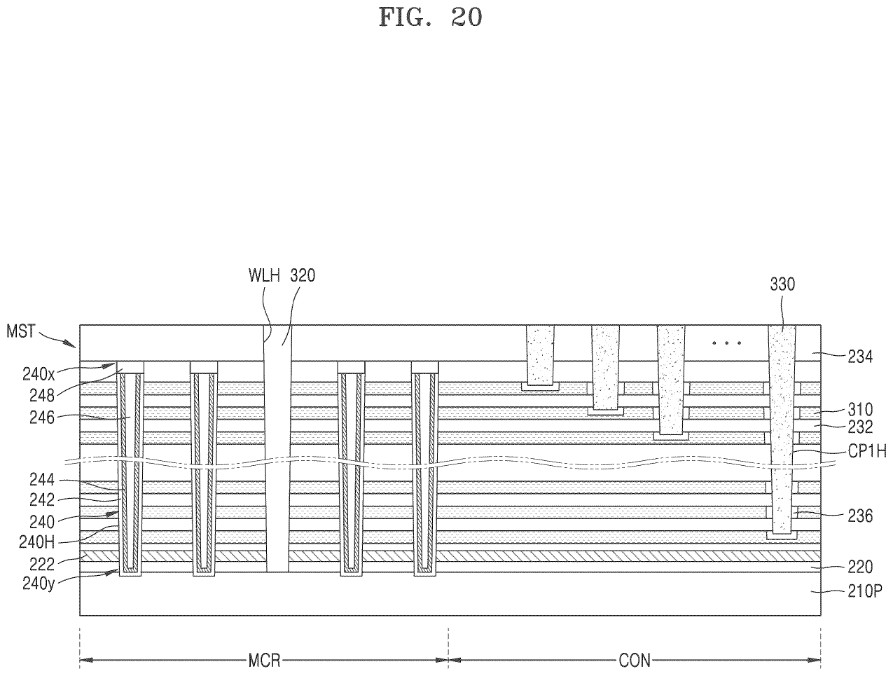

Referring to FIG. 20, protective pillars 330 may be formed within the plurality of cell plug holes CP1H.

A protective pillar 330 disposed in one cell plug hole CP1H may contact the sidewalls 232S of the plurality of mold insulating layers 232 and may contact the sidewalls 236S of the plurality of insulating spacers 236.

According to some example embodiments, the protective pillar 330 may include silicon oxide, silicon carbide, silicon, a spin-on hardmask, spin-on-dielectric, a metal, etc.

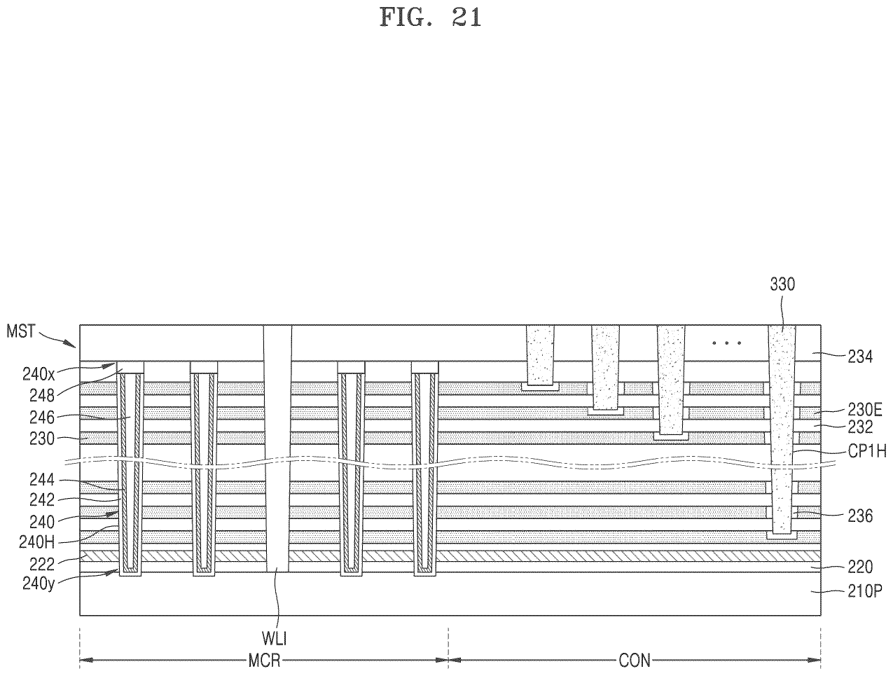

Referring to FIG. 21, the protective layer 320 disposed within the stack isolation opening WLH may be removed, and the sacrificial layers 310 exposed via the inner wall of the stack isolation opening WLH may be removed. Thereafter, the gate electrode 230 may be formed using a metal material in the space where the sacrificial layers 310 have been removed. Then, a stack isolation insulating layer WLI may be formed within the stack isolation opening WLH.

As the plurality of sacrificial layers 310 are replaced by the plurality of gate electrodes 230, the plurality of gate electrodes 230 may each extend in the horizontal direction in the cell region MCR and the connection region CON. The gate electrodes 230 disposed on the connection region CON are referred to as the gate extension 230E. In the connection region CON, a plurality of gate extensions 230E may overlap each other in the vertical direction. For example, the plurality of gate extensions 230E disposed at different vertical levels in the connection region CON may have the same width in the horizontal direction.

According to some example embodiments, the gate extensions 230E disposed in the connection region CON may be arranged to surround the insulating spacer 236, and a corresponding insulating spacer 236 may be disposed between one cell plug hole CP1H and each of the plurality of gate extensions 230E.

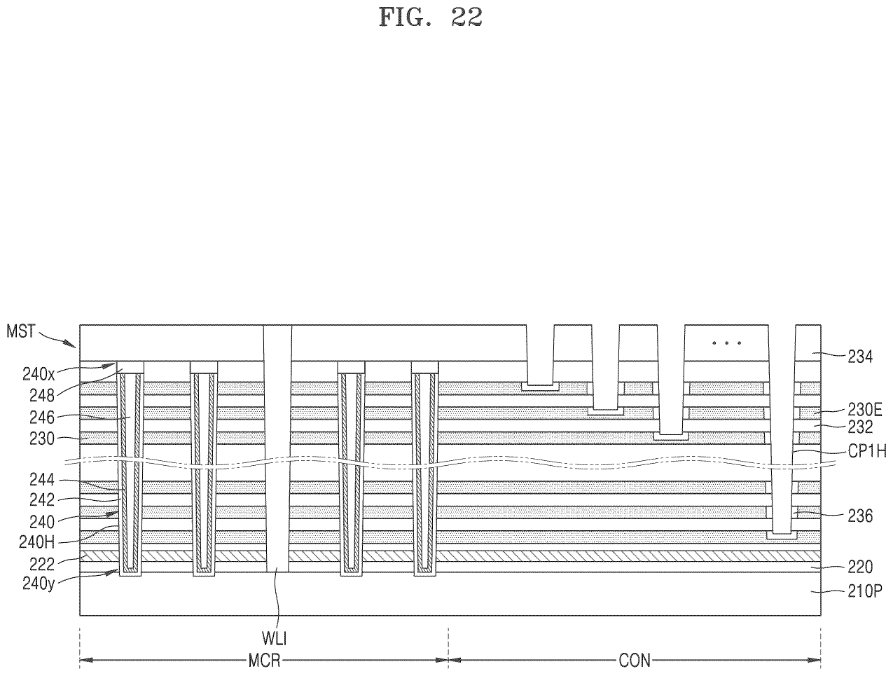

Referring to FIG. 22, the protective pillar 330 within the plurality of cell plug holes CP1H may be removed. As the protective pillar 330 is removed, the sidewall 232S of the mold insulating layer 232 and the sidewall 236S of the insulating spacer 236 may be exposed again.

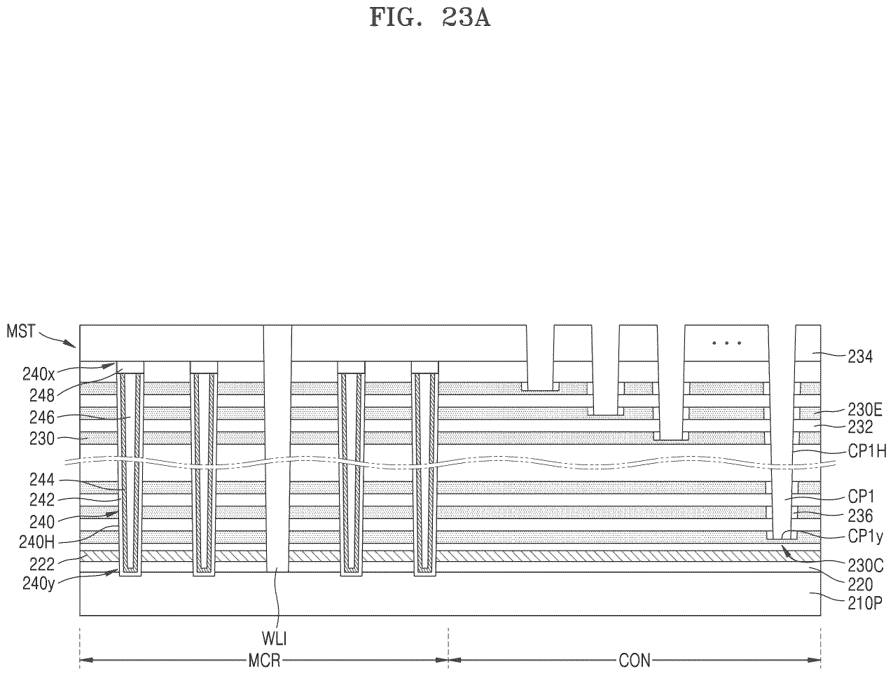

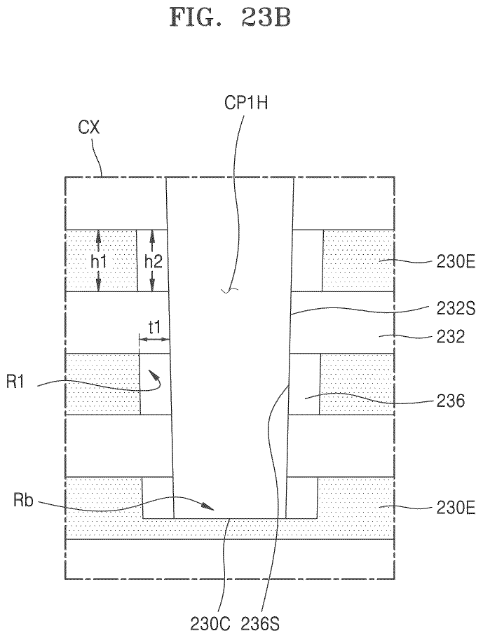

Referring to FIGS. 23A and 23B, an etch-back process may be performed on the bottom portions of the plurality of cell plug holes CP1H to remove a portion of the lowermost insulating spacer 236 disposed in the bottom portion of each of the plurality of cell plug holes CP1H and expose the upper surface of the gate extension 230E. According to some example embodiments, in the etch-back process, the lowermost insulating spacer 236 may be transformed from a closed-bottomed cup shape to a ring shape.

For example, a portion of the lowermost insulating spacer 236 that covers the upper surface of the gate extension 230E in the bottom recess region Rb may be removed by the etch-back process, and the upper surface of the gate extension 230E within the bottom recess region Rb may be exposed. The exposed upper surface of the gate extension 230E may be referred to as a gate contact surface 230C.

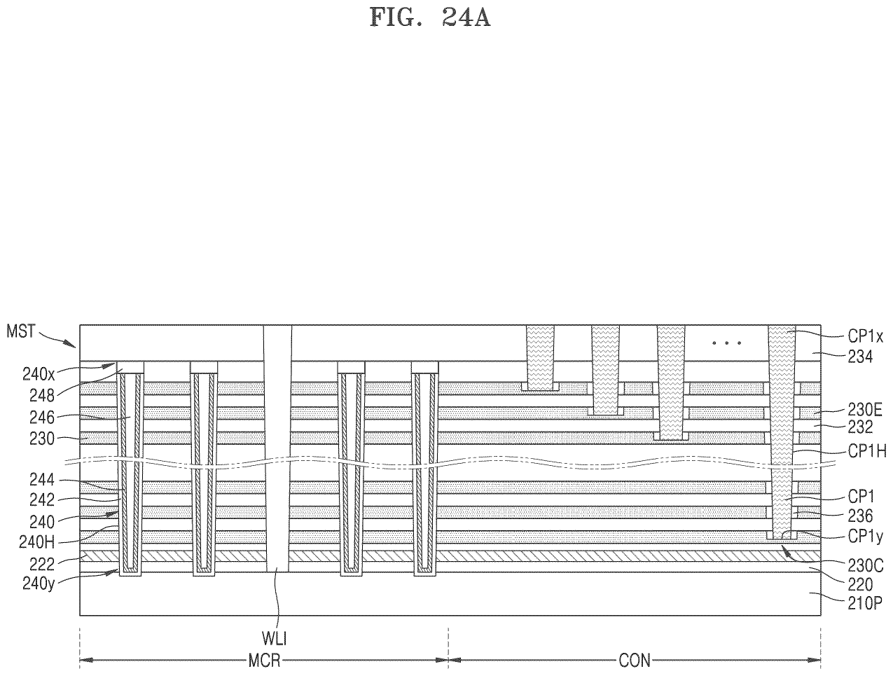

Referring to FIGS. 24A and 24B, a plurality of cell plugs CP1 may be respectively formed within the plurality of cell plug holes CP1H. Each of the plurality of cell plugs CP1 may have a plurality of first side surface portions CPS1 and a plurality of second side surface portions CPS2 alternating with each other (e.g., one cell plug CP1 may have a plurality of first side surface portions CPS1 and a plurality of second side surface portions CPS2 alternating with each other), and the plurality of first side surface portions CPS1 may be in contact with respective sidewalls 236S of a plurality of insulating spacers 236, and the plurality of second side surface portions CPS2 may be in contact with respective sidewalls 232S of a plurality of mold insulating layers 232. Because the sidewalls 232S of the plurality of mold insulating layers 232 and the sidewalls 236S of the plurality of insulating spacers 236 are aligned with each other and continuously connected to each other, the respective sidewalls of the plurality of cell plugs CP1 may also have a profile extending substantially vertically.

According to some example embodiments, each cell plug CP1 may have a first end CP1x and a second end CP1y, the first end CP1x of the cell plug CP1 may be disposed on the same level as the upper surface of the stack cover insulating layer 234, and the second end CP1y of the cell plug CP1 may be placed on a gate contact surface 230C corresponding to the cell plug CP1.

According to some example embodiments, respective bottom surfaces of the plurality of cell plugs CP1 may contact the gate contact surfaces 230C, and thus one cell plug CP1 may be electrically connected to a gate extension 230E corresponding thereto via the gate contact surface 230C.

For example, the bottom surface of one cell plug CP1 may be electrically connected to a corresponding gate extension 230E, whereas the sidewall of the one cell plug CP1 may not be electrically connected to a gate extension 230E disposed at a higher vertical level than the corresponding gate extension 230E. An insulating spacer 236 may be interposed between the gate extension 230E disposed at a higher vertical level than the corresponding gate extension 230E and the sidewall of the one cell plug CP1, and accordingly, the gate extension 230E disposed at a higher vertical level than the corresponding gate extension 230E and the sidewall of the one cell plug CP1 may be insulated from each other.

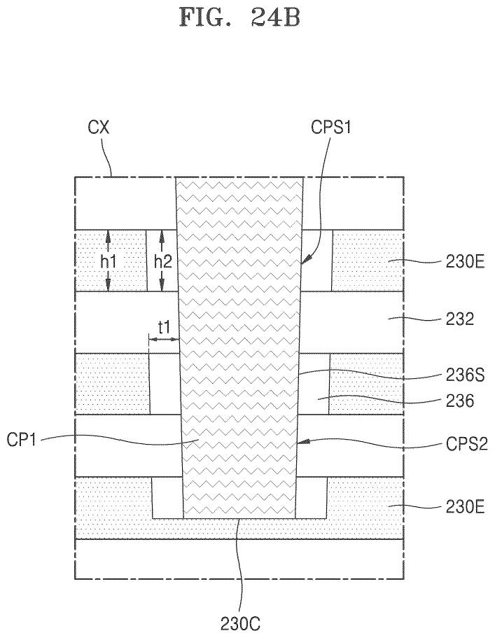

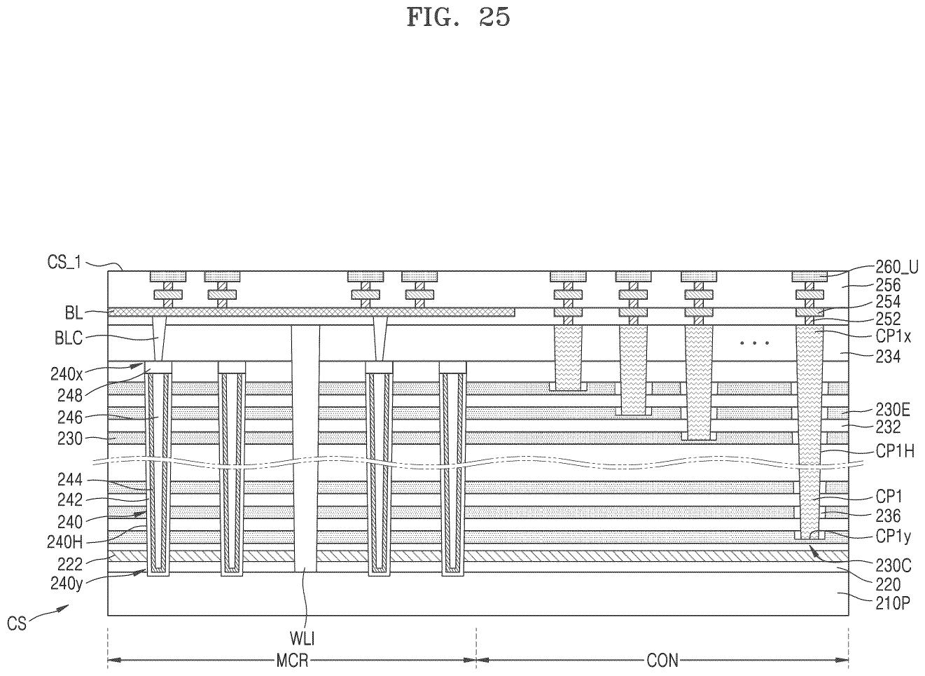

Referring to FIG. 25, a bit line contact BLC and a bit line BL electrically connected to the channel structure 240 may be formed.

Thereafter, a connection via 252 and a connection wiring layer 254 electrically connected to the bit line BL and the cell plug CP1, and an interlayer insulating layer 256 may be formed. A connection pad 260_U may be formed on an upper surface of the interlayer insulating layer 256.

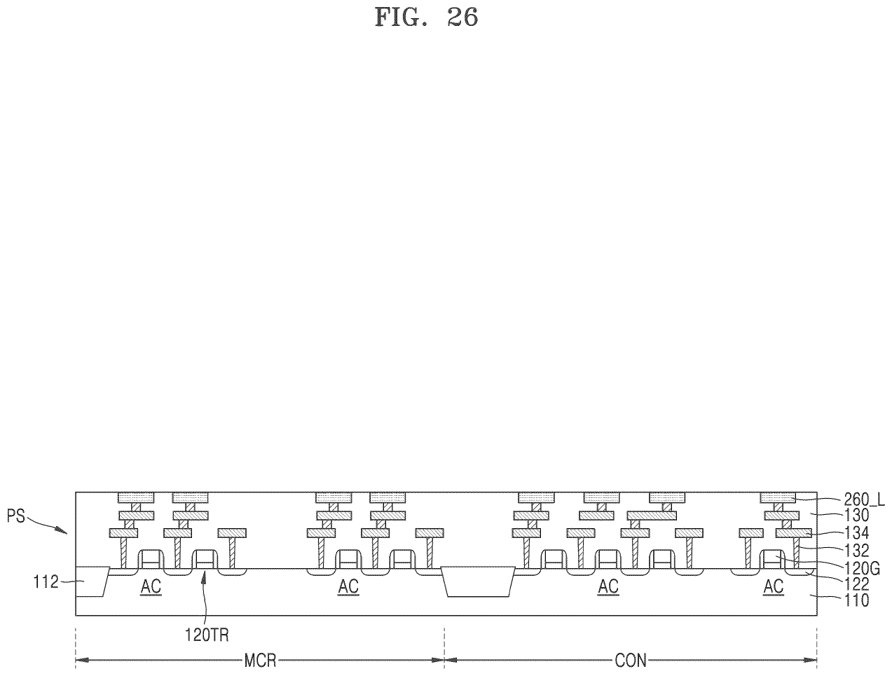

Referring to FIG. 26, the peripheral circuit structure PS may be prepared.

A peripheral circuit transistor 120TR may be formed on a substrate 110 in which an active area AC is defined by an isolation layer 112, a plurality of peripheral circuit contacts 132 and a plurality of peripheral circuit wiring layers 134 electrically connected to a plurality of peripheral circuit transistors 120TR and the substrate 110 may be formed on the substrate 110, and an interlayer insulating layer 130 covering the plurality of peripheral circuit transistors 120TR, the plurality of peripheral circuit contacts 132, and the plurality of peripheral circuit wiring layers 134 may be formed on the substrate 110. A connection pad 260_L may be formed on an upper surface of the interlayer insulating layer 130.

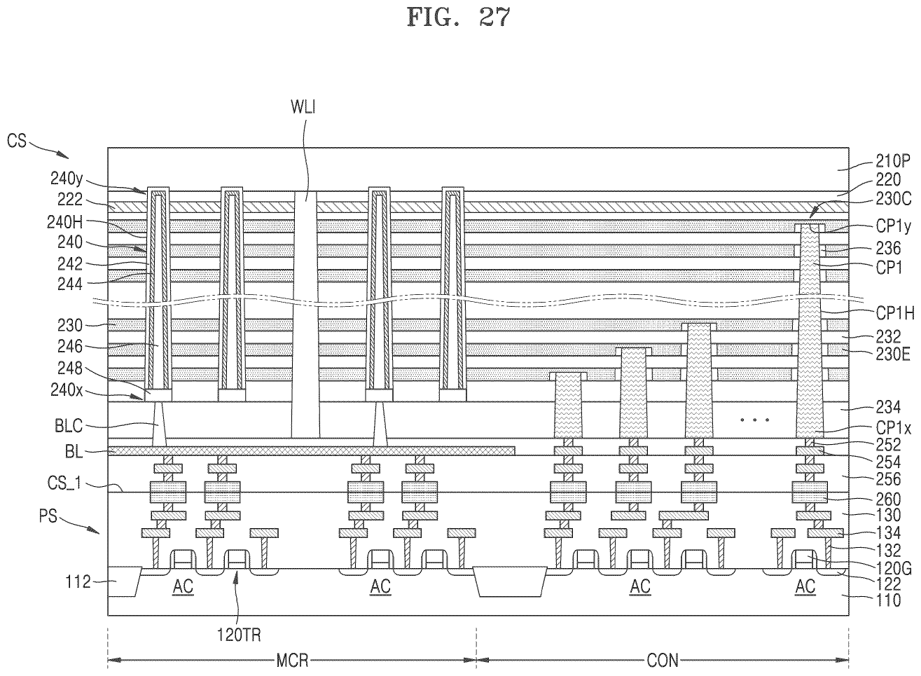

Referring to FIG. 27, the peripheral circuit structure PS may be attached to the cell structure CS. The peripheral circuit structure PS and the cell structure CS may be attached to each other through the connection pad 260 and the interlayer insulating layers 130 and 256 by using a metal-oxide hybrid bonding method, but embodiments are not limited thereto.

Thereafter, a structure in which the peripheral circuit structure PS and the cell structure CS are attached to each other may be turned over such that the substrate 110 faces upward.

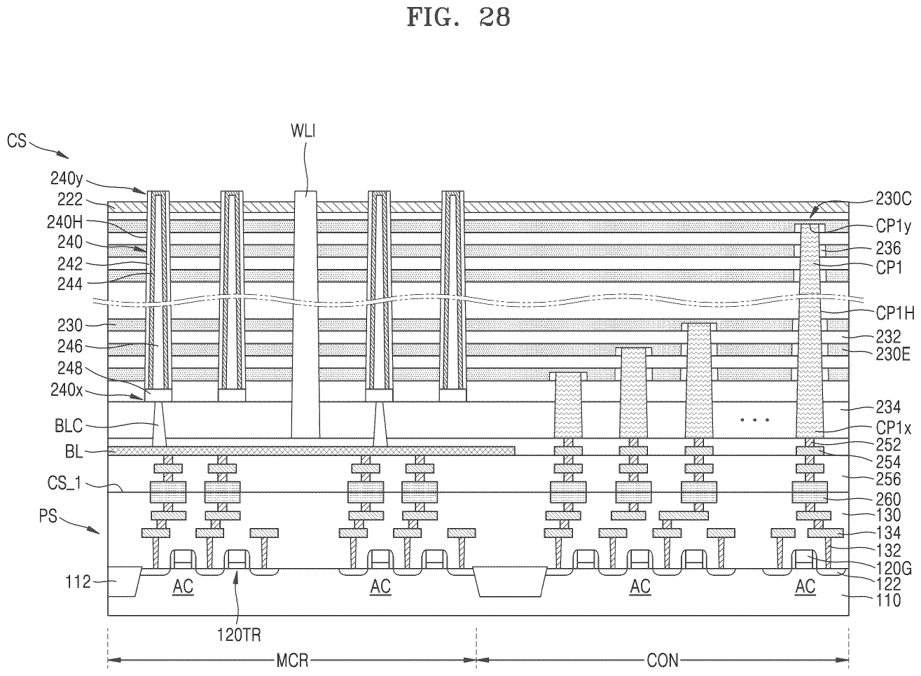

Referring to FIG. 28, the cell substrate 210P (see FIG. 18) may be removed. The cell substrate 210P may be removed by a grinding process and a subsequent etching process, and the buffer insulating layer 220 (see FIG. 27) may be exposed.

Thereafter, the buffer insulating layer 220 may also be removed and the upper surface of the etch stop layer 222 may be exposed. As the buffer insulating layer 220 is removed, the second end 240y of the channel structure 240 may protrude above the upper surface of the etch stop layer 222.

As the cell substrate 210P and the buffer insulating layer 220 are removed, the upper side of the stack isolation insulating layer WLI may also be exposed and may protrude above the etch stop layer 222.

Thereafter, a portion of the gate insulating layer 242 exposed via the second end 240y of the channel structure 240 may be removed to expose the upper surface of the channel layer 244. According to some example embodiments, the upper surface of the gate insulating layer 242 may be disposed on the same level as the upper surface of the channel layer 244.

According to some example embodiments, a process of removing the gate insulating layer 242 may be performed until the upper surface of the etch stop layer 222 is exposed. According to some example embodiments, the gate insulating layer 242 may be disposed at a lower level than the upper surface of the channel layer 244, and an upper side of the gate insulating layer 242 may be removed such that the upper surface of the channel layer 244 and a portion of the sidewalls thereof are exposed.

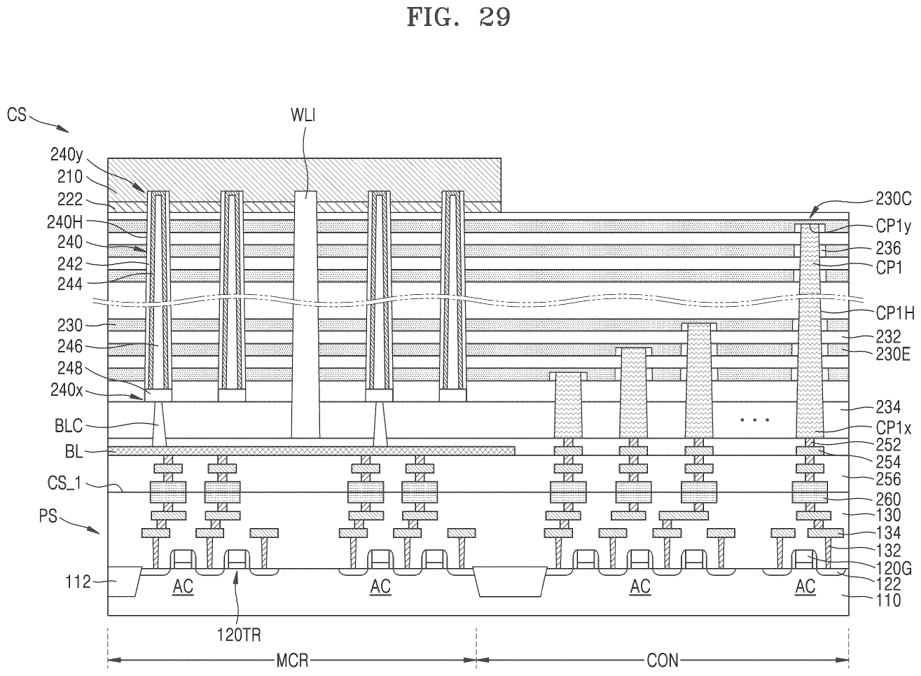

Referring to FIG. 29, the common source layer 210 may be formed on the cell region MCR, the connection region CON, and the peripheral circuit connection region PRC. The common source layer 210 may be formed using polysilicon. For example, the common source layer 210 may be formed of polysilicon doped with n-type impurities. In the cell region MCR, the common source layer 210 may be conformally formed on the exposed upper surfaces of the etch stop layer 222 and the channel layer 244.

A portion of the common source layer 210 and a portion of the etch stop layer 222 disposed in the connection region CON and the peripheral circuit connection region PRC may be removed.

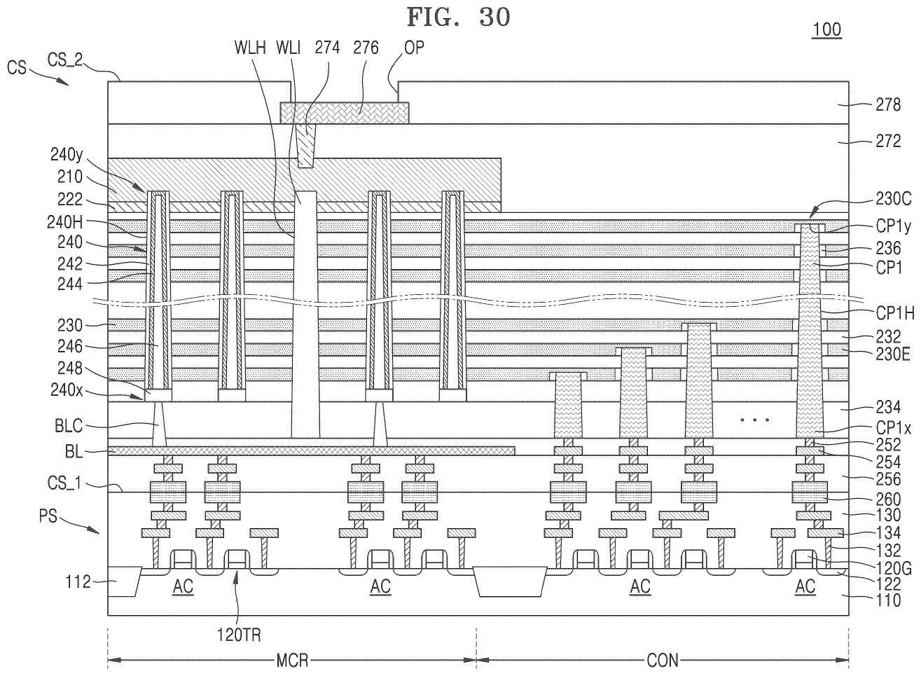

Referring to FIG. 30, the upper insulating layer 272 may be formed on the common source layer 210 and the uppermost mold insulating layer 232 in the cell region MCR, the connection region CON, and the peripheral circuit connection region PRC.

Thereafter, a mask pattern may be formed on the upper insulating layer 272, and a portion of the upper insulating layer 272 may be removed using the mask pattern as an etch mask to form a rear contact hole. A common source contact 274 may be formed within the rear contact hole, and a rear wiring layer 276 electrically connected to the common source contact 274 may be formed on the upper insulating layer 272.

Thereafter, a passivation layer 278 covering the rear wiring layer 276 may be formed on the upper insulating layer 272, and an opening OP may be formed in the passivation layer 278 to expose the upper surface of the rear wiring layer 276.

The semiconductor device 100 is completed by performing the above-described processes.

In general, a cell plug lands on a stair-shaped pad portion connected to a gate electrode in a connection region. However, as the number of layers of the gate electrode increases, the area occupied by the stair-shaped pad portion increases. To address this problem, a stair-free contact structure has been proposed that forms a cell plug hole penetrating the gate electrode and forms an insulating liner on the sidewall of the cell plug hole, instead of forming a stair-shaped pad portion. However, in the stair-free contact structure, because the aspect ratio of the cell plug hole is large, defects occur in a process of etching a bottom portion of the insulating liner, so that sufficient contact between the cell plug and the gate electrode is not secured.

According to the above-described embodiments, the cell plug CP1 may be formed to penetrate through the gate extensions 230E, and the insulating spacer 236 may be interposed between each of the gate extensions 230E and the sidewall of the cell plug CP1. Accordingly, the semiconductor device 100 has a stair-free contact structure, and thus the area occupied by the connection region CON may be minimized or reduced.

In addition, a recessed region R1 may be formed by removing a sacrificial layer 310 exposed on the inner wall of the cell plug hole CP1H, and the insulating spacer 236 may be formed within the recessed region R1, and thus the width of the second end CP1y of the cell plug CP1 may not decrease, and a sufficient contact area may be secured between the second end CP1y of the cell plug CP1 and the contact surface 230C of the gate extension 230E. Therefore, the semiconductor device 100 may have good electrical characteristics.

According to some example embodiments, because a semiconductor device has a stair-free contact structure, the area occupied by a connection area may be minimized or reduced. In addition, because a recess process is performed on the inner wall of a cell plug hole and an insulating spacer is formed using a self-alignment method, the width of a second end of a cell plug may not be reduced, and a sufficient contact area may be maintained between the second end of the cell plug and a gate electrode. Therefore, the semiconductor device may have good electrical characteristics.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As described herein, any electronic devices and/or portions thereof according to any of the example embodiments may include, may be included in, and/or may be implemented by one or more instances of processing circuitry such as hardware including logic circuits; a hardware/software combination such as a processor executing software; or any combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a DRAM device, storing a program of instructions, and a processor (e.g., CPU) configured to execute the program of instructions to implement the functionality and/or methods performed by some or all of any devices, systems, modules, units, controllers, circuits, architectures, and/or portions thereof according to any of the example embodiments, and/or any portions thereof.

While the inventive concepts has been particularly shown and described with reference to some example embodiments thereof, it will be understood that various changes in form and details may be made therein without departing from the spirit and scope of the following claims.

What is claimed is:

1. A semiconductor device comprising:
a peripheral circuit structure; and
a cell structure on the peripheral circuit structure and including a cell region and a connection region,
the cell structure comprising
gate electrodes and mold insulating layers alternately in a first direction perpendicular to an upper surface of the peripheral circuit structure in the cell region and the connection region;
a channel structure penetrating through the gate electrodes and extending in the first direction;
a cell plug contacting a first gate electrode among the gate electrodes in the connection region and penetrating through second gate electrodes below the first gate electrode among the gate electrodes; and
insulating spacers on a sidewall of the cell plug and spaced apart from each other in the first direction, each of the insulating spacers between each of the second gate electrodes and the sidewall of the cell plug.

2. The semiconductor device of claim 1, wherein
the cell plug is provided in plurality, and
the plurality of cell plugs have different heights.

3. The semiconductor device of claim 1, wherein, in a plan view, each of the insulating spacers has a ring shape.

4. The semiconductor device of claim 1, wherein
each of the second gate electrodes has a first height in the first direction, and
each of the insulating spacers has a second height that is equal to the first height in the first direction.

5. The semiconductor device of claim 1, wherein
a sidewall of the cell plug includes a first side surface portion and a second side surface portion,
the first side surface portion is in contact with the insulating spacers, and
the second side surface portion is in contact with the mold insulating layers.

6. The semiconductor device of claim 1, wherein the insulating spacers include silicon oxide containing any one element from among chlorine, fluorine, and bromine.

7. The semiconductor device of claim 1, further comprising:
a stack cover insulating layer below a lowest gate electrode among the gate electrodes;
a bit line below the channel structure and electrically connected to the channel structure; and
a connection pad electrically connected to the bit line and between the peripheral circuit structure and the cell structure,
wherein a first end of the cell plug penetrates through the stack cover insulating layer.

8. The semiconductor device of claim 7, wherein
the cell plug includes a second end opposite to the first end, and
the second end of the cell plug is in contact with the first gate electrode.

9. The semiconductor device of claim 8, wherein an upper surface of the second end of the cell plug is covered by a contact surface of the first gate electrode.

10. The semiconductor device of claim 1, wherein the upper surface of each of the insulating spacers is on a same plane as an upper surface of a corresponding second gate electrode among the second gate electrodes.

11. The semiconductor device of claim 1, wherein
the insulating spacers vertically overlap respective portions of the mold insulating layers, and
respective sidewalls of the insulating spacers and respective sidewalls of the mold insulating layers are aligned with each other and continuously connected to each other.

12. A semiconductor device comprising:
a peripheral circuit structure; and
a cell structure on the peripheral circuit structure and including a cell region and a connection region, the cell structure comprising
gate electrodes and mold insulating layers alternately in a first direction perpendicular to an upper surface of the peripheral circuit structure in the cell region and the connection region;
a channel structure penetrating through the gate electrodes and extending in the first direction;
a cell plug contacting a first gate electrode among the gate electrodes in the connection region and penetrating through second gate electrodes below the first gate electrode among the gate electrodes; and
insulating spacers on a first side surface portion of a sidewall of the cell plug, each of the insulating spacers between each of the second gate electrodes and the first side surface portion of the sidewall of the cell plug, and
a second side surface portion of the sidewall of the cell plug is in contact with the mold insulating layers.

13. The semiconductor device of claim 12, wherein
each of the second gate electrodes has a first height in the first direction, and
each of the insulating spacers has a second height that is equal to the first height in the first direction.

14. The semiconductor device of claim 12, wherein the insulating spacers include silicon oxide containing any one element from among chlorine, fluorine, and bromine.

15. The semiconductor device of claim 12, wherein, in a plan view, each of the insulating spacers has a ring shape.

16. The semiconductor device of claim 12, further comprising:
a stack cover insulating layer below a lowest gate electrode among the gate electrodes;
a bit line below the channel structure and electrically connected to the channel structure; and
a connection pad electrically connected to the bit line and between the peripheral circuit structure and the cell structure,
wherein
a first end of the cell plug penetrates through the stack cover insulating layer, and
a second end of the cell plug, opposite to the first end, is in contact with the first gate electrode.

17. The semiconductor device of claim 16, wherein
the cell plug is provided in plurality,
the plurality of cell plugs have different heights,
respective first ends of the plurality of cell plugs are on a same vertical level, and
respective second ends of the plurality of cell plugs are on different vertical levels.

18. The semiconductor device of claim 12, wherein
the insulating spacers vertically overlap respective portions of the mold insulating layers, and
respective sidewalls of the insulating spacers and respective sidewalls of the mold insulating layers are aligned with each other and continuously connected to each other.

19. A semiconductor device comprising:
a peripheral circuit structure; and
a cell structure on the peripheral circuit structure and including a cell region and a connection region,
wherein
the cell structure comprising
gate electrodes and mold insulating layers alternately in a first direction perpendicular to an upper surface of the peripheral circuit structure in the cell region and the connection region;
a channel structure penetrating through the gate electrodes and extending in the first direction in the cell region;
a stack cover insulating layer below a lowest gate electrode among the gate electrodes in the cell region and the connection region;
a cell plug contacting a first gate electrode among the gate electrodes in the connection region, penetrating through second gate electrodes below the first gate electrode among the gate electrodes, and including a first end close to the peripheral circuit structure and a second end opposite to the first end;
insulating spacers on a first side surface portion of a sidewall of the cell plug, each of the insulating spacers between each of the second gate electrodes and the first side surface portion of the sidewall of the cell plug; and
a bit line below the channel structure and electrically connected to the channel structure, and
a second side surface portion of the sidewall of the cell plug is in contact with the mold insulating layers.

20. The semiconductor device of claim 19, wherein
the insulating spacers include silicon oxide containing any one element from among chlorine, fluorine, and bromine, and
in a plan view, each of the insulating spacers has a ring shape.
